(19) United States
(12) Patent Application Publication
(10) Pub. No.: US 2026/0223508 A1
(43) Pub. Date: Jul. 30, 2026

(54) DISPLAY DEVICE, ELECTRONIC DEVICE AND METHOD FOR MANUFACTURING DISPLAY DEVICE

(71) Applicant: Samsung Display Co., Ltd., Yongin-si (KR)

(72) Inventors: Yu Jin LEE, Yongin-si (KR); Kyung Rock SON, Yongin-si (KR); Jae Phil LEE, Yongin-si (KR)

(21) Appl. No.: 19/394,290

(22) Filed: Nov. 19, 2025

(30) Foreign Application Priority Data
Jan. 24, 2025 (KR) 10-2025-0011475

(51) Int. Cl. H10H 29/49; H10H 29/01; H10H 29/41; H10H 29/855; H10H 29/856; H10K 59/12; H10K 59/124; H10K 59/131; H10K 59/80

(52) U.S. Cl. CPC H10H 29/49; H10H 29/012; H10H 29/0363; H10H 29/0364; H10H 29/41; H10H 29/8552; H10H 29/856; H10K 59/1201; H10K 59/124; H10K 59/131; H10K 59/8792

(57) ABSTRACT

A display device includes a pixel electrode and a common electrode on a substrate; an insulating layer on a portion of the pixel electrode and the common electrode; a light emitting element on the insulating layer, and including a semiconductor stack, and a first contact electrode and a second contact electrode on a side of the semiconductor stack; a first connection electrode on the insulating layer and a first side portion of a side surface of the light emitting element, the first connection electrode connecting the first contact electrode and the pixel electrode; a second connection electrode on the insulating layer and a second side portion of the side surface of the light emitting element, the second connection electrode connecting the second contact electrode and the common electrode; a first pattern on the first connection electrode, and a second pattern on the second connection electrode spaced from the first pattern.

### CROSS-REFERENCE TO RELATED APPLICATION

The present application claims priority to and the benefit of Korean Patent Application No. 10-2025-0011475 filed on Jan. 24, 2025, in the Korean Intellectual Property Office, the entire disclosure of which is incorporated herein by reference.

### BACKGROUND

### 1. Field

One or more aspects of embodiments of the present disclosure relate to a display device, an electronic device, and a method of manufacturing the display device.

### 2. Description of the Related Art

With the advance of information-oriented society, additional demands are placed on display devices and electronic devices capable of displaying images in various ways. In response to these demands, one or more suitable types (kinds) of display devices and electronic devices including pixels for displaying images are being developed. A display device may be provided alone, or may be included in an electronic device and used as a display screen of the electronic device.

### SUMMARY

One or more aspects of embodiments of the present disclosure provide a display device and an electronic device capable of improving light efficiency while preventing or reducing a short circuit defect, and a method for manufacturing the display device.

However, aspects of the present disclosure are not restricted to the ones set forth herein. The above and other aspects of the present disclosure will become more apparent to one of ordinary skill in the art to which the present disclosure pertains by referencing the detailed description of the present disclosure given herein below.

According to one or more embodiments of the present disclosure, there is provided a display device including a pixel electrode and a common electrode located on a substrate, an insulating layer located on a portion of the pixel electrode and the common electrode, a light emitting element located on the insulating layer, and including a semiconductor stack, and a first contact electrode and a second contact electrode located on a side surface of the semiconductor stack, a first connection electrode located on the insulating layer and on a first side portion of a side surface of the light emitting element, which includes the first contact electrode, the first connection electrode connecting the first contact electrode and the pixel electrode, a second connection electrode located on the insulating layer and on a second side portion of the side surface of the light emitting element, which includes the second contact electrode, the second connection electrode connecting the second contact electrode and the common electrode, a first pattern located on the first connection electrode and around (e.g., surrounding) the first side portion of the light emitting element, and a second pattern located on the second connection electrode, around (e.g., surrounding) the second side portion of the light emitting element, and spaced apart from the first pattern.

In one or more embodiments, the first pattern and the second pattern may include a negative type or kind photoresist material and may include a side surface having a reverse tapered shape.

In one or more embodiments, the display device may further include a first reflective film located on a side surface of the first pattern and around (e.g., surrounding) the first side portion of the light emitting element, and a second reflective film located on a side surface of the second pattern and around (e.g., surrounding) the second side portion of the light emitting element.

In one or more embodiments, an angle formed by at least a part of the first reflective film and the pixel electrode may be 100° to 120°, and an angle formed by at least a part of the second reflective film and the common electrode may be 100° to 120°.

In one or more embodiments, the first pattern and the second pattern may include a light-transmissive organic material through which light emitted from the light emitting element can be transmitted.

In one or more embodiments, a height of the first pattern may be greater than or equal to a height of the first connection electrode, and a height of the second pattern may be greater than or equal to a height of the second connection electrode.

In one or more embodiments, the first pattern, when viewed in plan view (e.g., from above), may have a shape and size corresponding to the first connection electrode, and the second pattern, when viewed in plan view (e.g., from above), may have a shape and size corresponding to the second connection electrode.

In one or more embodiments, the side surface of the light emitting element further may include a third side portion between the first side portion and the second side portion, and the first connection electrode and the second connection electrode may be spaced apart from each other with the third side portion of the light emitting element interposed between the first connection electrode and the second connection electrode.

In one or more embodiments, the first pattern and the second pattern may be spaced apart from each other with the third side portion of the light emitting element interposed between the first pattern and the second pattern.

In one or more embodiments, display device may further include a light blocking layer located on a side surface of the first pattern and a side surface of the second pattern, and the light blocking layer may surround at least a part of the light emitting element including the first side portion and the second side portion.

According to one or more embodiments of the present disclosure, there is provided an electronic device including a display module including a display panel, and a processor to transmit an image data signal to the display module, wherein the display panel includes a pixel electrode and a common electrode located on a substrate, an insulating layer located on a portion of the pixel electrode and the common electrode, a light emitting element located on the insulating layer, and including a semiconductor stack, and a first contact electrode and a second contact electrode located on a side surface of the semiconductor stack, a first connection electrode located on the insulating layer and on a first side portion of a side surface of the light emitting element, which includes the first contact electrode, the first connection electrode connecting the first contact electrode and the pixel electrode, a second connection electrode located on the insulating layer and on a second side portion of the side surface of the light emitting element, which includes the second contact electrode, the second connection electrode connecting the second contact electrode and the common electrode, a first pattern located on the first connection electrode and around (e.g., surrounding) the first side portion of the light emitting element, and a second pattern located on the second connection electrode, around (e.g., surrounding) the second side portion of the light emitting element, and spaced apart from the first pattern.

In one or more embodiments, the first pattern and the second pattern may include a negative type or kind photoresist material and may include a side surface having a reverse tapered shape.

In one or more embodiments, the display panel may further include a first reflective film located on a side surface of the first pattern and around (e.g., surrounding) the first side portion of the light emitting element, and a second reflective film located on a side surface of the second pattern and around (e.g., surrounding) the second side portion of the light emitting element.

In one or more embodiments, an angle formed by at least a part of the first reflective film and the pixel electrode may be 100° to 120°, and an angle formed by at least a part of the second reflective film and the common electrode may be 100° to 120°.

In one or more embodiments, the first pattern, when viewed in plan view (e.g., from above), may have a shape and size corresponding to the first connection electrode, and the second pattern, when viewed in plan view (e.g., from above), may have a shape and size corresponding to the second connection electrode.

In one or more embodiments, the display panel may further include a light blocking layer located on a side surface of the first pattern and a side surface of the second pattern, and the light blocking layer may surround at least a part of the light emitting element including the first side portion and the second side portion.

According to one or more embodiments of the present disclosure, there is provided a method for manufacturing a display device, including forming a pixel electrode and a common electrode on a substrate; forming an insulating layer covering a portion of the pixel electrode and the common electrode; arranging, on the insulating layer, a light emitting element including a semiconductor stack, and a first contact electrode and a second contact electrode located on a side surface of the semiconductor stack; forming a conductive film on the pixel electrode, the common electrode, the insulating layer and the light emitting element; forming, on the conductive film, a first pattern around (e.g., surrounding) a first side portion of a side surface of the light emitting element, which includes the first contact electrode, and a second pattern around (e.g., surrounding) a second side portion of the side surface of the light emitting element, which includes the second contact electrode; and forming a first connection electrode around (e.g., surrounding) the first side portion of the light emitting element and connecting the first contact electrode and the pixel electrode, and a second connection electrode around (e.g., surrounding) the second side portion of the light emitting element and connecting the second contact electrode and the common electrode by etching the conductive film, using (e.g., utilizing) the first pattern and the second pattern as a mask.

In one or more embodiments, in the forming of the first pattern and the second pattern, the first pattern and the second pattern may be formed in a shape including a side surface having a reverse tapered shape, using a negative type or kind photoresist material.

In one or more embodiments, the method may further include forming a first reflective film and a second reflective film on the side surface of the first pattern and the side surface of the second pattern, respectively.

In one or more embodiments, the method may further include forming a light blocking layer around (e.g., surrounding) at least a part of the light emitting element including the first side portion and the second side portion, on the side surfaces of the first pattern and the second pattern.

A display device and an electronic device according to one or more embodiments may include a first connection electrode connecting a portion of a light emitting element to a pixel electrode, a second connection electrode connecting another portion of the light emitting element to a common electrode, a first pattern located on the first connection electrode, and a second pattern located on the second connection electrode and spaced apart from the first pattern. In some embodiments, the first connection electrode and the second connection electrode may be formed under the first pattern and the second pattern, respectively, by utilizing the first pattern and the second pattern (e.g., as a mask). In accordance with the display device, the electronic device, and the method for manufacturing the display device according to the embodiments, the first connection electrode and the second connection electrode may be stably or suitably separated to prevent or reduce a short circuit defect between the pixel electrode and the common electrode.

In some embodiments, the first pattern and the second pattern may surround different side portions of the light emitting element, and may include side surfaces having a reverse tapered shape. In addition, the display device and the electronic device may further include a first reflective film and a second reflective film that are arranged on the side surfaces of the first pattern and the second pattern and are inclined at a shape and/or angle corresponding to the side surfaces of the first pattern and the second pattern, respectively. In accordance with the display device and the electronic device, and the method for manufacturing the display device according to the embodiments, the reflectivity of the lateral light heading toward the first reflective film and the second reflective film may be increased, and the light efficiency of the display device and the electronic device may be improved.

However, effects according to the embodiments of the present disclosure are not limited to those exemplified above and one or more suitable other effects are incorporated herein.

### BRIEF DESCRIPTION OF THE DRAWINGS

The above and other aspects and features of the present disclosure will become more apparent by describing in more detail embodiments thereof with reference to the attached drawings, in which:

FIG. 1 is a perspective view illustrating a display device according to one or more embodiments;

FIG. 2 is a plan view illustrating a display panel according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is a plan view illustrating a display panel according to one or more embodiments;

FIG. 6 is a plan view illustrating a display panel according to one or more embodiments;

FIG. 7 is a cross-sectional view illustrating a display panel according to one or more embodiments;

FIG. 8 is a cross-sectional view showing area A1 of FIG. 7 in more detail;

FIGS. 9-19 are cross-sectional views showing a method for manufacturing the display device according to one or more embodiment;

FIG. 20 is a block diagram of an electronic device according to one or more embodiments; and

FIG. 21 is schematic views of electronic devices according to one or more suitable embodiments.

### DETAILED DESCRIPTION

The present disclosure will now be described more fully hereinafter with reference to the accompanying drawings, in which embodiments of the invention are shown. This disclosure may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer is referred to as being “on” another element or layer, it can be directly on the other element or layer (e.g., without any intervening layers present), or intervening layers may also be present.

The same reference numbers indicate the same components throughout the specification.

It will be understood that, although the terms “first,” “second,” and/or the like may be used herein to describe one or more suitable elements, these elements should not be limited by these terms. These terms are only used to distinguish one element from another element. For instance, a first element discussed below could be termed a second element without departing from the teachings of the present disclosure. Similarly, the second element could also be termed the first element.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

It will be understood that when an element is referred to as being “on,” “connected to,” or “coupled to” another element, it may be directly on, connected, or coupled to the other element or one or more intervening elements may also be present. When an element is referred to as being “directly on,” “directly connected to,” or “directly coupled to” another element, there are no intervening elements present.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Features of each of one or more suitable embodiments of the present disclosure may be partially or entirely combined with each other and may technically variously interwork with each other, and respective embodiments may be implemented independently of each other or may be implemented together in association with each other.

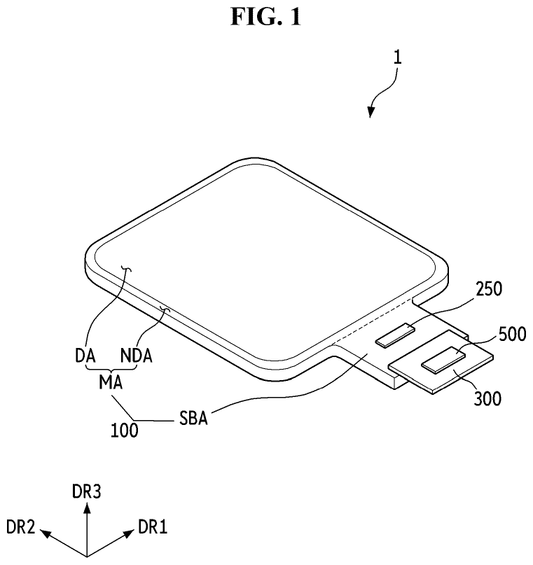

FIG. 1 is a perspective view illustrating a display device according to one or more embodiments.

Referring to FIG. 1, a display device 1 may be a device capable of providing an image, such as a moving image and/or a still image. For example, the display device 1 may be a device that includes a display module including a display panel 100 and thus may display an image. For example, the display device 1 may refer to any suitable electronic device that can provide a display screen on which an image may be displayed and/or include a display module for displaying an image. The display device 1 may be included in an electronic device that provides a display screen and may form the display screen of the electronic device.

For example, the display device 1 may be included in one or more suitable electronic devices such as televisions, laptop computers, monitors, billboards and/or the Internet of Things (IOT), as well as portable electronic devices such as mobile phones, smart phones, tablet personal computers (tablet PCs), smart watches, watch phones, mobile communication terminals, electronic notebooks, electronic books, portable multimedia players (PMPs), navigation systems and/or ultra mobile PCs (UMPCs), and used as a display screen. In one or more embodiments, the display device 1 may be included in other electronic devices such as a virtual reality (VR) device, an augmented reality (AR) device, and/or the like and used to display an image in the electronic device.

In FIG. 1, a display module, which is a main component of the display device 1, is illustrated. In one or more embodiments, the display device 1 (or an electronic device including a display module) may further include one or more additional components. For example, the display device 1 may further include a housing or a casing that accommodates the display module of FIG. 1.

In one or more embodiments, the display device 1 may be a light emitting display device such as an organic light emitting display using an organic light emitting diode, a quantum dot light emitting display including a quantum dot light emitting layer, an inorganic light emitting display including an inorganic semiconductor, and/or a micro or nano light emitting display using a micro or nano light emitting diode (LED). Hereinafter, as an example of the display device 1 to which embodiments may be applied, a micro or nano light emitting display including a micro or nano light emitting diode will be disclosed. However, the embodiments are not limited thereto. For example, the type or kind of light emitting element included in the display device 1 is not limited to a micro or nano light emitting diode, and the display device 1 may include a light emitting element of another type or kind and/or shape. Further, the display device 1 according to one or more embodiments is not limited to a light emitting display device, and the type or kind and/or shape of the display device 1 may vary depending on embodiments.

The display device 1 may include a display panel 100, a display driving circuit 250, a circuit board 300, and a power supply unit 500. The display panel 100, the display driving circuit 250, the circuit board 300, and the power supply unit 500 may be included in the display module of the display device 1.

In one or more embodiments, the display panel 100 may have a substantially quadrilateral planar shape. For example, the display panel 100 may have a substantially quadrilateral shape on the plane defined by a first direction DR1 and a second direction DR2 intersecting each other. The corners of the display panel 100 may be rounded or may be right-angled. The planar shape of the display panel 100 is not limited to the rectangular shape, and may be formed in another polygonal shape, a circular shape, or an elliptical shape. The display panel 100 may be substantially flat, but the present disclosure is not limited thereto. For example, the display panel 100 may include a curved portion in at least a part (e.g., at left and/or right ends). In one or more embodiments, the display panel 100 may be formed to be flexible so that it can be curved, bent, folded, and/or rolled.

The display panel 100 may include a main region MA where an image is displayed. In one or more embodiments, the display panel 100 may further include a sub-region SBA.

The main region MA may include a display area DA displaying an image and a non-display area NDA that is a peripheral area of the display area DA. The display area DA may include pixels for displaying an image. Each of the pixels may include a plurality of sub-pixels. For example, each of the pixels may include a first sub-pixel that is to emit light of a first color, a second sub-pixel that is to emit light of a second color, and a third sub-pixel that is to emit light of a third color, but the embodiments are not limited thereto.

The sub-region SBA may protrude from one side of the main region MA in the second direction DR2 (e.g., the longitudinal direction). Although FIG. 1 shows a state in which the sub-region SBA is unfolded, the sub-region SBA may be bent. When the sub-region SBA is bent, the sub-region SBA may overlap the main region MA in a third direction DR3, which is the thickness direction of the display panel 100, and may be located on the bottom surface of the display panel 100. The display driving circuit 250 may be arranged in the sub-region SBA.

The display driving circuit 250 may generate signals and voltages (for example, driving signals and driving voltages of the display panel 100) for driving the display panel 100. The display driving circuit 250 may be formed as an integrated circuit (IC) and attached onto the display panel 100 by a chip on glass (COG) method, a chip on plastic (COP) method, and/or an ultrasonic bonding method, but the present disclosure is not limited thereto. For example, the display driving circuit 250 may be attached onto the circuit board 300 by a chip on film (COF) method.

The circuit board 300 may be attached to one end of the sub-region SBA of the display panel 100, and may be electrically connected to the display panel 100 and the display driving circuit 250. The display panel 100 and the display driving circuit 250 may receive digital video data, timing signals, and/or driving voltages through the circuit board 300. The circuit board 300 may be a flexible printed circuit board, a printed circuit board, and/or a flexible film such as a chip on film.

The power supply unit 500 may generate panel driving voltages according to a power voltage supplied from the outside. The power supply unit 500 may be formed as an integrated circuit (IC) and attached to the circuit board 300 by a COF method.

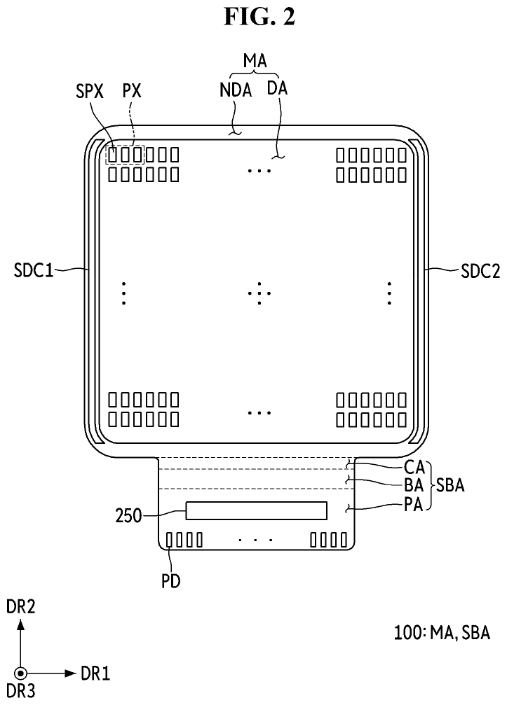

FIG. 2 is a plan view illustrating a display panel according to one or more embodiments. In FIG. 2, the sub-region SBA is illustrated in an unfolded state.

Referring to FIGS. 1 and 2, the display panel 100 may include the main region MA and the sub-region SBA.

The main region MA may include the display area DA and the non-display area NDA. The display area DA may occupy most (e.g., a larger portion) of the main region MA.

The display area DA may include pixels PX for displaying an image. Each of the pixels PX may include a plurality of sub-pixels SPX. The pixel PX may be defined as a minimum unit sub-pixel group capable of expressing a white grayscale. For example, the pixel PX may include three sub-pixels SPX that emit light of different colors. However, the number, type or kind, and/or ratio of the sub-pixels SPX included in each pixel PX may vary depending on embodiments.

The non-display area NDA may be located adjacent to the display area DA. For example, the non-display area NDA may surround the display area DA. The non-display area NDA may be an edge area of the display panel 100.

In one or more embodiments, a first scan driver SDC1 and a second scan driver SDC2 may be located in the non-display area NDA. The first scan driver SDC1 and the second scan driver SDC2 may be located on different sides of the display area DA (e.g., opposite sides of the display area DA facing each other). Each of the first scan driver SDC1 and the second scan driver SDC2 may be electrically connected to the display driving circuit 250 through a plurality of wires. Each of the first scan driver SDC1 and the second scan driver SDC2 may receive scan control signals input from the display driving circuit 250, generate scan signals in response to the scan control signals, and output the generated scan signals to scan lines.

Although FIG. 2 shows one or more embodiments in which the display device 1 (for example, the display panel 100) includes the first scan driver SDC1 and the second scan driver SDC2, the embodiments are not limited thereto. For example, the number and/or location of the scan driver included in the display device 1 may vary depending on embodiments.

The sub-region SBA may protrude from one side of the main region MA in the second direction DR2 (e.g., the longitudinal direction). The length of the sub-region SBA in the second direction DR2 may be less than the length of the main region MA in the second direction DR2. The length of the sub-region SBA in the first direction DR1 may be less than or equal to the length of the main region MA in the first direction DR1. The sub-region SBA may be bent, so that at least a part of the sub-region SBA may overlap the main region MA in the third direction DR3. For example, a part of the sub-region SBA, when bent, may be located under the main region MA.

The sub-region SBA may include a connection area CA, a pad area PA, and a bending area BA.

The connection area CA may be an area protruding from one side of the main region MA in the second direction DR2. One side of the connection area CA may be in contact with the non-display area NDA of the main region MA, and the other side of the connection area CA may be in contact with the bending area BA.

The pad area PA may be an area on which pads PD and the display driving circuit 250 are arranged. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA may be an area being bent. When the display panel 100 is bent in the bending area BA, the pad area PA may be located under the connection area CA and the main region MA. The bending area BA may be located between the connection area CA and the pad area PA. One side of the bending area BA may be in contact with the connection area CA, and the other side of the bending area BA may be in contact with the pad area PA.

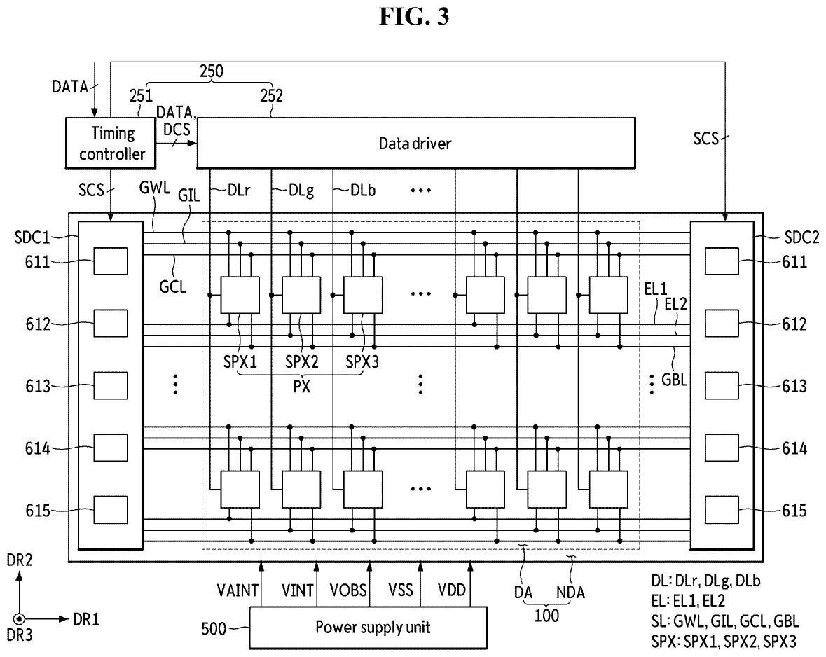

FIG. 3 is a block diagram illustrating a display device according to one or more embodiments.

Referring to FIG. 3, the display area DA may include pixels PX, scan lines SL, emission control lines EL, and data lines DL.

The pixels PX may be arranged in the first direction DR1 and the second direction DR2. For example, the pixels PX may be arranged in a matrix form in the first direction DR1 and the second direction DR2. The scan lines SL and the emission control lines EL may extend in the first direction DR1 and be arranged in the second direction DR2. The data lines DL may extend in the second direction DR2 and may be arranged along the first direction DR1. The scan lines SL may include write scan lines GWL, initialization scan lines GIL, control scan lines GCL, and bias scan lines GBL. The configuration of the scan lines SL may be different according to the structure or driving method of the pixels PX.

Each of the pixels PX may include a plurality of sub-pixels SPX. For example, each of the pixels PX may include a first sub-pixel SPX1, a second sub-pixel SPX2, and a third sub-pixel SPX3. The first sub-pixel SPX1, the second sub-pixel SPX2, and the third sub-pixel SPX3 may be to emit light of a first color, light of a second color, and light of a third color, respectively. The light of the first color, the light of the second color, and the light of the third color may be red light (for example, light in a red wavelength band having a main peak wavelength of about 600 nm to 750 nm), green light (for example, light in a green wavelength band having a main peak wavelength of about 480 nm to 560 nm), and blue light (for example, light in a blue wavelength band having a main peak wavelength of about 370 nm to 460 nm), respectively, but the present disclosure is not limited thereto. In one or more embodiments, the first sub-pixel SPX1, the second sub-pixel SPX2, and the third sub-pixel SPX3 of each of the pixels PX may be arranged in the first direction DR1. The number, type or kind, arrangement structure, and/or emission wavelength of the sub-pixels SPX included in each of the pixels PX may vary depending on the embodiments.

Each of the sub-pixels SPX may be connected to any one of the write scan lines GWL, any one of the initialization scan lines GIL, any one of the control scan lines GCL, any one of the bias scan lines GBL, any one of the emission control lines EL, and any one of the data lines DL. In describing embodiments, “connection” may include “physical connection” and/or “electrical connection.”

Each of the plurality of sub-pixels SPX may receive the data voltage of the data line DL according to the write scan signal of the write scan line GWL. Each of the plurality of sub-pixels SPX may include a light emitting element that emits light with a luminance corresponding to the data voltage. The plurality of sub-pixels SPX included in each pixel PX may be connected to the different data lines DL. For example, the first sub-pixel SPX1, the second sub-pixel SPX2, and the third sub-pixel SPX3 may be respectively connected to a first data line DLr, a second data line DLg, and a third data line DLb. Accordingly, the luminance of each of the first sub-pixel SPX1, the second sub-pixel SPX2, and the third sub-pixel SPX3 may be controlled or selected individually.

In one or more embodiments, each of the pixels PX may be connected to two or more emission control lines EL, and an emission period (or on-duty ratio) of at least two of the sub-pixels SPX included in each pixel PX may be controlled or selected independently and/or individually by different emission control signals supplied to the different emission control lines EL. For example, in each horizontal line (e.g., each pixel row) of the display area DA, a first emission control line EL1 and a second emission control line EL2, which are connected to different sub-pixels SPX among the sub-pixels SPX of the pixels PX arranged on the corresponding horizontal line, may be located. For example, the first emission control line EL1 may be connected to the first sub-pixels SPX1 of the pixels PX arranged on the corresponding horizontal line, and the second emission control line EL2 may be connected to the second sub-pixels SPX2 and the third sub-pixels SPX3 included in the pixels PX of the corresponding horizontal line.

The first sub-pixel SPX1 may be to emit light during a first emission period in response to a first emission control signal supplied through the first emission control line EL1. The first emission period may be a period during which a driving current may flow through the first sub-pixel SPX1 by the first emission control signal. The second sub-pixel SPX2 and the third sub-pixel SPX3 may be to emit light during a second emission period in response to a second emission control signal supplied through the second emission control line EL2. The second emission period may be a period during which a driving current may flow through the second sub-pixel SPX2 and the third sub-pixel SPX3 by the second emission control signal. The first emission period and the second emission period may be controlled or selected independently or separately from each other.

In one or more embodiments, the duration of the first emission period may be different from the duration of the second emission period. For example, the duration of the first emission period may correspond to an on-duty ratio adjusted to allow the first sub-pixel SPX1 to emit light with a desired or suitable luminance according to a driving current improved or optimized according to the luminous efficiency of the first sub-pixel SPX1 (e.g., a driving current in a range in which the light emitting element of the first sub-pixel SPX1 exhibits the optimal or suitable consumption efficiency). The duration of the second emission period may correspond to an on-duty ratio adjusted to allow the second sub-pixel SPX2 and the third sub-pixel SPX3 to emit light with a desired or suitable luminance according to a driving current improved or optimized according to the luminous efficiency of the second sub-pixel SPX2 and the third sub-pixel SPX3 (e.g., a driving current in a range in which the light emitting elements of the second sub-pixel SPX2 and the third sub-pixel SPX3 exhibit the optimal or suitable consumption efficiency). In this case, an emission control signal output unit 615 included in the first scan driver SDC1 and the second scan driver SDC2 may output emission control signals having different pulse widths to the first emission control line EL1 and the second emission control line EL2.

However, the embodiments are not limited thereto. For example, in another embodiment, the first sub-pixel SPX1, the second sub-pixel SPX2, and the third sub-pixel SPX3 included in one pixel PX may be commonly connected to one emission control line EL. For example, one emission control line EL may be located in one horizontal line, and the sub-pixels SPX located in the one horizontal line may be commonly connected to the one emission control line EL. In this case, the emission periods of the first sub-pixel SPX1, the second sub-pixel SPX2, and the third sub-pixel SPX3 may be controlled or selected by the emission control signal supplied to the one emission control line EL.

The first scan driver SDC1, the second scan driver SDC2, and the display driving circuit 250 may be located in the non-display area NDA and the sub-region SBA (see FIG. 2).

Each of the first scan driver SDC1 and the second scan driver SDC2 may be electrically connected to the pixels PX through the scan lines SL and the emission control lines EL. For example, each of the first scan driver SDC1 and the second scan driver SDC2 may be electrically connected to the sub-pixels SPX of each pixel PX through the write scan lines GWL, the initialization scan lines GIL, the control scan lines GCL, the bias scan lines GBL, and the emission control lines EL.

Each of the first scan driver SDC1 and the second scan driver SDC2 may include a write scan signal output unit 611, an initialization scan signal output unit 612, a control scan signal output unit 613, a bias scan signal output unit 614, and the emission control signal output unit 615. Each of the write scan signal output unit 611, the initialization scan signal output unit 612, the control scan signal output unit 613, the bias scan signal output unit 614, and the emission control signal output unit 615 may receive a scan timing control signal SCS from a timing controller 251.

The write scan signal output unit 611 may generate write scan signals in response to the scan timing control signal SCS and sequentially output them to the write scan lines GWL.

The initialization scan signal output unit 612 may generate initialization scan signals in response to the scan timing control signal SCS and sequentially output them to the initialization scan lines GIL.

The control scan signal output unit 613 may generate control scan signals in response to the scan timing control signal SCS and sequentially output them to the control scan lines GCL.

The bias scan signal output unit 614 may generate bias scan signals according to the scan timing control signal SCS and output them sequentially to the bias scan lines GBL.

The emission control signal output unit 615 may generate emission control signals according to the scan timing control signal SCS and sequentially output them to the emission control lines EL. In one or more embodiments, if (e.g., when) the sub-pixels SPX of each horizontal line are divided and connected to the plurality of emission control lines EL (e.g., the first emission control line EL1 and the second emission control line EL2 of each horizontal line), the emission control signal output unit 615 may output each emission control signal to the plurality of emission control lines EL for each horizontal period.

The display driving circuit 250 may include the timing controller 251 and a data driver 252.

The data driver 252 may be electrically connected to the pixels PX through the data lines DL. For example, the data driver 252 may be electrically connected to the sub-pixels SPX of each pixel PX through the first data line DLr, the second data line DLg, and the third data line DLb.

The data driver 252 may receive the digital video data DATA and the data timing control signal DCS from the timing controller 251. The data driver 252 converts the digital video data DATA into analog data voltages in response to the data timing control signal DCS, and outputs them to the data lines DL. The sub-pixels SPX may be selected by the write scan signal of the first scan driver SDC1 and the second scan driver SDC2, and data voltages may be supplied to the selected sub-pixels SPX.

The timing controller 251 may receive digital video data DATA and timing signals from the outside. The timing controller 251 may generate the scan timing control signal SCS and the data timing control signal DCS for controlling the display panel 100 in response to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate panel driving voltages according to a power voltage supplied from the outside. For example, the power supply unit 500 may generate and supply a first driving voltage VDD, a second driving voltage VSS, a third driving voltage VINT, a fourth driving voltage VAINT, and a fifth driving voltage VOBS to the display panel 100. The first driving voltage VDD, the second driving voltage VSS, the third driving voltage VINT, the fourth driving voltage VAINT, and the fifth driving voltage VOBS may be supplied to the sub-pixels SPX through respective power lines connected between the power supply unit 500 and the sub-pixels SPX, and may be used to drive the sub-pixels SPX. According to the structure or operation method of the sub-pixels SPX, the number and/or type or kind of panel driving voltages outputted from the power supply unit 500 may be changed.

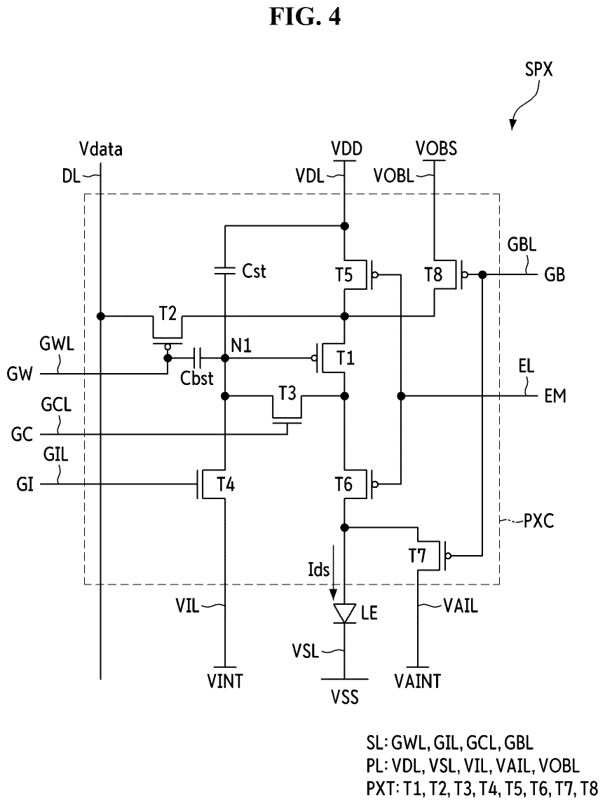

FIG. 4 is an equivalent circuit diagram illustrating a sub-pixel according to one or more embodiments. For example, FIG. 4 may be an equivalent circuit diagram showing one sub-pixel SPX among the sub-pixels SPX of FIGS. 2 and 3. For example, the sub-pixel SPX of FIG. 4 may be the first sub-pixel SPX1, the second sub-pixel SPX2, and/or the third sub-pixel SPX3 of FIG. 3. In one or more embodiments, the circuit configurations of the sub-pixels SPX constituting each pixel PX may be substantially the same.

Referring to FIG. 4 in addition to FIGS. 1 to 3, each of the sub-pixels SPX may include a pixel circuit PXC and a light emitting element LE electrically connected to the pixel circuit PXC.

The sub-pixel SPX may be connected to at least one scan driver through the scan lines SL and the emission control line EL. For example, the sub-pixel SPX may be connected to the first scan driver SDC1 and the second scan driver SDC2 through the write scan line GWL, the initialization scan line GIL, the control scan line GCL, the bias scan line GBL, and the emission control line EL. The first scan driver SDC1 and the second scan driver SDC2 may output the write scan signal GW, the initialization scan signal GI, the control scan signal GC, the bias scan signal GB, and the emission control signal EM to the write scan line GWL, the initialization scan line GIL, the control scan line GCL, the bias scan line GBL, and the emission control line EL, respectively.

When the sub-pixel SPX is the first sub-pixel SPX1, the sub-pixel SPX may be connected to the first emission control line EL1 located on the corresponding horizontal line, and may receive the emission control signal EM (also referred to as “first emission control signal”) from the first emission control line EL1. When the sub-pixel SPX is the second sub-pixel SPX2 or the third sub-pixel SPX3, the sub-pixel SPX may be connected to the second emission control line EL2 located on the corresponding horizontal line, and may receive the emission control signal EM (also referred to as “second emission control signal”) from the second emission control line EL2.

The sub-pixel SPX may be connected to the data driver 252 through the data line DL. The data driver 252 may output a data voltage Vdata corresponding to the image data of each frame to the data line DL.

When the sub-pixel SPX is the first sub-pixel SPX1, the sub-pixel SPX may be connected to the first data line DLr located in the corresponding pixel column. When the sub-pixel SPX is the second sub-pixel SPX2, the sub-pixel SPX may be connected to the second data line DLg located in the corresponding pixel column. When the sub-pixel SPX is the third sub-pixel SPX3, the sub-pixel SPX may be connected to the third data line DLb located in the corresponding pixel column.

The sub-pixel SPX may be connected to the power supply unit 500 through power lines PL. For example, the sub-pixel SPX may be connected to the power supply unit 500 through a first power line VDL, a second power line VSL, a third power line VIL, a fourth power line VAIL, and a fifth power line VOBL. The power supply unit 500 may supply the first driving voltage VDD, the second driving voltage VSS, the third driving voltage VINT, the fourth driving voltage VAINT, and the fifth driving voltage VOBS to the first power line VDL, the second power line VSL, the third power line VIL, the fourth power line VAIL, and the fifth power line VOBL, respectively. In one or more embodiments, the first driving voltage VDD, the second driving voltage VSS, the third driving voltage VINT, the fourth driving voltage VAINT, and the fifth driving voltage VOBS may be a high potential pixel voltage (e.g., an anode voltage), a low potential pixel voltage (e.g., a cathode voltage or common voltage), a first initialization voltage (e.g., a gate initialization voltage), a second initialization voltage (e.g., an anode initialization voltage), and a bias voltage, respectively.

The pixel circuit PXC may control a driving current Ids supplied to the light emitting element LE in response to the driving signals (e.g., the write scan signal GW, the initialization scan signal GI, the control scan signal GC, the bias scan signal GB, the emission control signal EM, and the data voltage Vdata) supplied to the sub-pixel SPX. The emission timing and luminance of the light emitting element LE may be controlled or selected by the pixel circuit PXC.

The pixel circuit PXC may include pixel transistors PXT and a storage capacitor Cst. In one or more embodiments, the pixel circuit PXC may further include a boosting capacitor Cbst.

In one or more embodiments, the pixel transistors PXT may include first to eighth transistors T1 to T8. The first transistor T1 may be a driving transistor of the sub-pixel SPX. The second to eighth transistors T2 to T8 may be switching transistors of the sub-pixel SPX.

In one or more embodiments, the sub-pixel SPX may include different types (kinds) of pixel transistors PXT. For example, the first, second, fifth, sixth, seventh, and eighth transistors T1, T2, T5, T6, T7, and T8 may be P-type transistors (e.g., P-type polycrystalline silicon transistors including active layers containing polycrystalline silicon), and the third and fourth transistors T3 and T4 may be N-type transistors (e.g., N-type oxide transistors including active layers containing an oxide semiconductor). In one or more embodiments, the active layers of P-type transistors (e.g., the active layers containing polycrystalline silicon) and the active layers of N-type transistors (e.g., the active layers containing an oxide semiconductor) may be located in different layers within the display panel 100 (e.g., a backplane layer of the display panel 100). However, the embodiments are not limited thereto. For example, the pixel transistors PXT according to one or more other embodiments may include active layers including the same semiconductor material, and may be formed as transistors of the same type or kind.

The first transistor T1 may be connected between the fifth transistor T5 and the sixth transistor T6. The first transistor T1 may be connected to the first power line VDL via the fifth transistor T5, and may be connected to the light emitting element LE via the sixth transistor T6. The gate electrode of the first transistor T1 may be connected to a first node N1. The first transistor T1 may control the driving current Ids flowing through the sub-pixel SPX according to the voltage of the first node N1 applied to the gate electrode (for example, a voltage corresponding to the data voltage Vdata).

The second transistor T2 may be connected between the data line DL and the first electrode of the first transistor T1 (e.g., the source electrode of the first transistor T1 connected to the fifth transistor T5). The gate electrode of the second transistor T2 may be connected to the write scan line GWL. The second transistor T2 may be turned on by the write scan signal GW of a gate-on voltage (for example, a low-level voltage at which the second transistor T2 can be turned on) supplied from the write scan line GWL. When the second transistor T2 is turned on, the data voltage Vdata supplied from the data line DL may be transmitted to the first electrode (e.g., the source electrode) of the first transistor T1.

The third transistor T3 may be connected between the second electrode of the first transistor T1 (e.g., the drain electrode of the first transistor T1 connected to the sixth transistor T6) and a first node N1. The gate electrode of the third transistor T3 may be connected to the control scan line GCL. The third transistor T3 may be turned on by the control scan signal GC of a gate-on voltage (e.g., a suitably high level voltage at which the third transistor T3 can be turned on) supplied from the control scan line GCL to connect the gate electrode of the first transistor T1 to the second electrode of the first transistor T1. When the third transistor T3 is turned on, the first transistor T1 may be driven as a diode, and a voltage corresponding to the data voltage Vdata may be applied to the first node N1.

The fourth transistor T4 may be connected between the first node N1 and the third power line VIL. The gate electrode of the fourth transistor T4 may be connected to the initialization scan line GIL. The fourth transistor T4 may be turned on by the initialization scan signal GI of a gate-on voltage (e.g., a suitably high level voltage at which the fourth transistor T4 can be turned on) supplied from the initialization scan line GIL to connect the first node N1 to the third power line VIL. When the fourth transistor T4 is turned on, the voltage of the first node N1 may be initialized to the third driving voltage VINT of the third power line VIL.

The fifth transistor T5 may be connected between the first power line VDL and the first electrode of the first transistor T1. The gate electrode of the fifth transistor T5 may be connected to the emission control line EL (e.g., the first emission control line EL1 or the second emission control line EL2 of FIG. 3). The fifth transistor T5 may be turned on by the emission control signal EM of a gate-on voltage (e.g., a suitably low level voltage at which the fifth transistor T5 can be turned on) supplied from the emission control line EL to connect the first electrode of the first transistor T1 to the first power line VDL. When the fifth transistor T5 is turned on, the first power line VDL may be connected to the first electrode of the first transistor T1.

The sixth transistor T6 may be connected between the second electrode of the first transistor T1 and the light emitting element LE. The gate electrode of the sixth transistor T6 may be connected to the emission control line EL. The sixth transistor T6 may be turned on by the emission control signal EM of a gate-on voltage (e.g., a suitably low level voltage at which the sixth transistor T6 can be turned on) supplied from the emission control line EL to connect the second electrode of the first transistor T1 to the light emitting element LE.

The seventh transistor T7 may be connected between the first electrode of the light emitting element LE (e.g., the anode electrode connected to the sixth transistor T6) and the fourth power line VAIL. The gate electrode of the seventh transistor T7 may be connected to the bias scan line GBL. The seventh transistor T7 may be turned on by the bias scan signal GB of a gate-on voltage (e.g., a suitably low level voltage at which the seventh transistor T7 can be turned on) supplied from the bias scan line GBL to connect the first electrode of the light emitting element LE to the fourth power line VAIL. When the seventh transistor T7 is turned on, the voltage of the first electrode of the light emitting element LE may be initialized to the fourth driving voltage VAINT of the fourth power line VAIL.

The eighth transistor T8 may be connected between the fifth power line VOBL and the first electrode of the first transistor T1. The gate electrode of the eighth transistor T8 may be connected to the bias scan line GBL. The eighth transistor T8 may be turned on by the bias scan signal GB of a gate-on voltage supplied from the bias scan line GBL to connect the first electrode of the first transistor T1 to the fifth power line VOBL. When the eighth transistor T8 is turned on, the voltage of the first electrode of the first transistor T1 may be initialized to the fifth driving voltage VOBS of the fifth power line VOBL. In one or more embodiments, the fifth driving voltage VOBS may be a bias voltage having a voltage level suitable for compensating the hysteresis characteristics of the first transistor T1.

The storage capacitor Cst may be connected between the first node N1 and the first power line VDL. The storage capacitor Cst may be charged with a voltage corresponding to the data voltage Vdata applied to the first node N1.

The boosting capacitor Cbst may be connected between the first node N1 and the write scan line GWL. The voltage of the first node N1 may be stabilized by the coupling aspect of the boosting capacitor Cbst, thereby stabilizing or improving the stability of the operation of the first transistor T1. The boosting capacitor Cbst may be formed by a parasitic capacitance formed between the first node N1 and the write scan line GWL, or may be designed separately.

The sub-pixel SPX may be to emit light during a partial period of each frame period, which corresponds to the on-duty ratio, and may not emit light during the remaining period. The emission period and non-emission period of the sub-pixel SPX may be controlled or selected by the emission control signal EM.

A period during which the fifth transistor T5 and the sixth transistor T6 are turned off (e.g., a period during which the emission control signal EM of a suitably high level is supplied to the sub-pixel SPX) may be a non-emission period of the sub-pixel SPX. The non-emission period of the sub-pixel SPX may include an initialization period for initializing a voltage of a specific node (e.g., the first node N1 and/or the like) of the sub-pixel SPX, and a data write and storage period for charging the storage capacitor Cst with a voltage corresponding to the data voltage Vdata.

In one or more embodiments, the initialization scan signal GI, the control scan signal GC, the write scan signal GW, and the bias scan signal GB of a gate-on voltage may be supplied during the non-emission period of the sub-pixel SPX. In one or more embodiments, the initialization scan signal GI, the control scan signal GC, and the bias scan signal GB of the gate-on voltage may be sequentially supplied during the non-emission period of the sub-pixel SPX. The periods in which the initialization scan signal GI and the control scan signal GC of the gate-on voltage are supplied may overlap, but the present disclosure is not limited thereto. The write scan signal GW of the gate-on voltage may be supplied during the period when the control scan signal GC of the gate-on voltage is supplied.

The period during which the fifth transistor T5 and the sixth transistor T6 are turned on (e.g., the period during which the emission control signal EM of a suitably low level is supplied to the sub-pixel SPX) may be an emission period of the sub-pixel SPX. During the emission period of the sub-pixel SPX, the first transistor T1 may supply the driving current Ids corresponding to the voltage of the first node N1 to the light emitting element LE.

The light emitting element LE may be connected between the pixel circuit PXC and the second power line VSL. For example, the first electrode (e.g., the anode electrode or pixel electrode) of the light emitting element LE may be connected to a node between the sixth transistor T6 and the seventh transistor T7, and the second electrode (e.g., the cathode electrode or common electrode) of the light emitting element LE may be connected to the second power line VSL. The light emitting element LE may be to emit light to correspond to the driving current Ids supplied from the pixel circuit PXC.

In one or more embodiments, the sub-pixel SPX may include a single light emitting element LE, but the present disclosure is not limited thereto. For example, the sub-pixel PX may include a plurality of light emitting elements LE.

In one or more embodiments, the light emitting element LE may be a micro light emitting diode containing an inorganic compound such as a nitride-based and/or phosphide-based semiconductor material, but the present disclosure is not limited thereto. For example, the light emitting element LE may be an organic light emitting element, a quantum dot light emitting element, or another type or kind of light emitting element. In one or more embodiments, the size and/or shape of the light emitting element LE may be different (e.g., may vary) according to the embodiments.

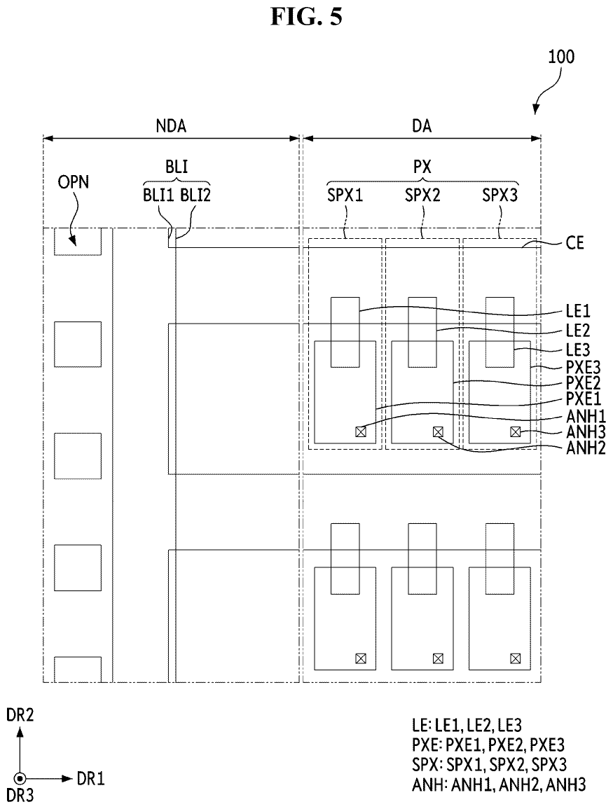

FIG. 5 is a plan view illustrating a display panel according to one or more embodiments. For example, FIG. 5 shows a part of the display area DA where two pixels PX are sequentially located in the second direction DR2, and a part of the non-display area NDA adjacent to the display area DA and where a power bus line BLI is located.

FIG. 5 shows an example of a layout structure of a light emitting element layer including the light emitting elements LE of the sub-pixels SPX. The display panel 100 may further include a backplane layer including circuit elements of the sub-pixels SPX (for example, circuit elements included in each of the pixel circuits PXC of the sub-pixels SPX).

Referring to FIG. 5, each of the sub-pixels SPX may include the pixel electrode PXE, and the light emitting element LE located on the pixel electrode PXE. In one or more embodiments, when the light emitting element LE is a micro LED of a flip-chip type or kind or a lateral type or kind, each of the sub-pixels SPX may further include the common electrode CE located on one surface (for example, a bottom surface or top surface) of the light emitting element LE together with the pixel electrode PXE. In another embodiment, when the light emitting element LE is a micro LED of a vertical type or kind, the light emitting element LE of each of the sub-pixels SPX may be located on the pixel electrode PXE, and the common electrode CE (for example, the common electrode CE located as a common layer in the entire display area DA) may be located on the light emitting elements LE of the sub-pixels SPX. FIG. 5 shows the display panel 100 including the light emitting elements LE of a flip-chip type or kind. The pixel electrode PXE may also be referred to as the anode electrode or the first electrode, and the common electrode CE may also be referred to as the cathode electrode or the second electrode.

In one or more embodiments, the sub-pixels SPX of each pixel PX may be arranged in the first direction DR1 and may share one common electrode CE. For example, the common electrode CE may extend in the first direction DR1 in each pixel row (e.g., horizontal line) of the display area DA, and the sub-pixels SPX of the pixels PX located on the corresponding pixel row may share one common electrode CE.

In one or more embodiments, the sub-pixels SPX of the display area DA may be arranged in a stripe shape (e.g., stripe formation). For example, in each pixel column including the pixels PX arranged in the second direction DR2 in the display area DA, the first sub-pixels SPX1 may be arranged sequentially or continuously in the second direction DR2. In one or more embodiments, the second sub-pixels SPX2 included in each pixel column may be arranged sequentially or continuously in the second direction DR2, and the third sub-pixels SPX3 included in each pixel column may be arranged sequentially or continuously in the second direction DR2. However, the arrangement form of the pixels PX and/or the sub-pixels SPX may vary depending on embodiments.

The first sub-pixel SPX1 may include a first pixel electrode PXE1 and the common electrode CE (or a part of the common electrode CE) spaced apart from each other, and a first light emitting element LE1 located on the first pixel electrode PXE1 and the common electrode CE. The first pixel electrode PXE1 may refer to the pixel electrode PXE of the first sub-pixel SPX1, and the first light emitting element LE1 may refer to the light emitting element LE of the first sub-pixel SPX1. The first light emitting element LE1 may be electrically connected between the first pixel electrode PXE1 and the common electrode CE.

The second sub-pixel SPX2 may include a second pixel electrode PXE2 and the common electrode CE spaced apart from each other, and a second light emitting element LE2 located on the second pixel electrode PXE2 and the common electrode CE. The second pixel electrode PXE2 may refer to the pixel electrode PXE of the second sub-pixel SPX2, and the second light emitting element LE2 may refer to the light emitting element LE of the second sub-pixel SPX2. The second light emitting element LE2 may be electrically connected between the second pixel electrode PXE2 and the common electrode CE.

The third sub-pixel SPX3 may include a third pixel electrode PXE3 and the common electrode CE spaced apart from each other, and a third light emitting element LE3 located on the third pixel electrode PXE3 and the common electrode CE. The third pixel electrode PXE3 may refer to the pixel electrode PXE of the third sub-pixel SPX3, and the third light emitting element LE3 may refer to the light emitting element LE of the third sub-pixel SPX3. The third light emitting element LE3 may be electrically connected between the third pixel electrode PXE3 and the common electrode CE.

In one or more embodiments, the first pixel electrode PXE1, the second pixel electrode PXE2, and the third pixel electrode PXE3 of each pixel PX may be sequentially arranged along the first direction DR1, and may be spaced apart from the common electrode CE in the second direction DR2. The first pixel electrode PXE1, the second pixel electrode PXE2, and the third pixel electrode PXE3 may face different parts of the common electrode CE in the second direction DR2. In one or more other embodiments, when the sub-pixels SPX include a micro LED of a vertical type or kind, the first pixel electrode PXE1, the second pixel electrode PXE2, and the third pixel electrode PXE3 may face the common electrode CE in the third direction DR3.

The pixel circuit PXC (see FIG. 4) and the pixel electrode PXE of each of the sub-pixels SPX may be electrically connected to each other through an anode contact hole ANH (or first contact hole). For example, the first pixel electrode PXE1 of the first sub-pixel SPX1 may be electrically connected to at least one circuit element (for example, the sixth and seventh transistors T6 and T7 of FIG. 4) included in the pixel circuit PXC of the first sub-pixel SPX1 through the first anode contact hole ANH1 and/or at least one connection pattern. Similarly, the second pixel electrode PXE2 of the second sub-pixel SPX2 may be electrically connected to at least one circuit element included in the pixel circuit PXC of the second sub-pixel SPX2 through a second anode contact hole ANH2 and/or at least one connection pattern, and the third pixel electrode PXE3 of the third sub-pixel SPX3 may be electrically connected to at least one circuit element included in the pixel circuit PXC of the third sub-pixel SPX3 through a third anode contact hole ANH3 and/or at least one connection pattern.

The light emitting elements LE may be located between the respective pixel electrodes PXE and the common electrode CE. For example, the first light emitting element LE1 may be located on the first pixel electrode PXE1 and the common electrode CE, and a part of the first light emitting element LE1 may overlap the first pixel electrode PXE1 and another part of the first light emitting element LE1 may overlap the common electrode CE. The second light emitting element LE2 may be located on the second pixel electrode PXE2 and the common electrode CE, and a part of the second light emitting element LE2 may overlap the second pixel electrode PXE2 and another part of the second light emitting element LE2 may overlap the common electrode CE. The third light emitting element LE3 may be located on the third pixel electrode PXE3 and the common electrode CE, and a part of the third light emitting element LE3 may overlap the third pixel electrode PXE3 and another part of the third light emitting element LE3 may overlap the common electrode CE.

Each of the light emitting elements LE may be to emit light of a set or specific color (for example, red light, green light, blue light, or white light). In one or more embodiments, the first light emitting element LE1, the second light emitting element LE2, and the third light emitting element LE3 may be to emit light of different colors. For example, the first light emitting element LE1, the second light emitting element LE2, and the third light emitting element LE3 may be to emit light of a first color (for example, red light), light of a second color (for example, green light), and light of a third color (for example, blue light), respectively.

In one or more embodiments, the first light emitting element LE1, the second light emitting element LE2, and the third light emitting element LE3 may be to emit light of the same color. In this case, at least one selected from among a color filter and a light conversion layer (for example, light conversion layer including wavelength conversion particles such as quantum dots and/or the like) for converting light emitted from the light emitting element LE of the corresponding sub-pixel SPX to light corresponding to the emission color of the corresponding sub-pixel SPX may be located on at least one light emitting element LE of the first sub-pixel SPX1, the second sub-pixel SPX2, and/or the third sub-pixel SPX3.

The first light emitting element LE1, the second light emitting element LE2, and the third light emitting element LE3 may have substantially the same size, but are not limited thereto. By way of example, depending on the light efficiency of the light emitting elements LE and/or the sub-pixels SPX, at least two light emitting elements LE selected from among the first light emitting element LE1, the second light emitting element LE2 and the third light emitting element LE3 may have different sizes.

The common electrode CE may be electrically connected to the power bus line BLI (e.g., a cathode bus line) to which the second driving voltage VSS is applied. In one or more embodiments, the common electrode CE may extend to the non-display area NDA around the display area DA, and may be electrically connected to the power bus line BLI in the non-display area NDA. The common electrode CE may be electrically connected to the power bus line BLI through at least one contact hole and/or connection line, or may be integrally formed with at least a part of the power bus line BLI. For example, the power bus line BLI may include a plurality of wiring layers, and one of the plurality of wiring layers and the common electrode CE may be formed as substantially one pattern.

In one or more embodiments, the second power line VSL (see FIG. 4) to which the second driving voltage VSS is applied may be located also in the display area DA. For example, the second power line VSL intersecting or overlapping the common electrode CE may be located in the backplane layer located under the common electrode CE. In this case, the common electrode CE may be electrically connected to the second power line VSL through at least one contact hole and/or connection line in the display area DA.

The power bus line BLI may be located in the non-display area NDA, and may be located on at least one side of the display area DA. For example, the power bus line BLI may be located on the left side and the right side of the display area DA, and may be further selectively located on at least one selected from among the upper side and the lower side of the display area DA. In FIG. 5, a part of the power bus line BLI located on the left side of the display area DA is illustrated.

The power bus line BLI may be electrically connected to the power supply unit 500 (see FIG. 3). For example, the power bus line BLI may be electrically connected to the power supply unit 500 through at least one pad PD and/or at least one connection line located in the sub-region SBA and/or the non-display area NDA of the main region MA. Accordingly, the second driving voltage VSS outputted from the power supply unit 500 may be applied to the power bus line BLI. The power bus line BLI may form a part of the second power line VSL electrically connected between the power supply unit 500 and the sub-pixels SPX. In one or more embodiments, the connection structure between the common electrode CE and the second power line VSL may be changed in one or more suitable ways depending on embodiments.

In one or more embodiments, the power bus line BLI may be formed as multiple layers including the first wiring layer BLI1 and the second wiring layer BLI2. The first wiring layer BLI1 and the second wiring layer BLI2 may be electrically connected to each other.

The first wiring layer BLI1 may be located in substantially the same layer as the pixel electrodes PXE and the common electrode CE, and may include a conductive material included in the pixel electrodes PXE and the common electrode CE. In one or more embodiments, the first wiring layer BLI1 may be integrally formed with the common electrode CE. For example, at least one end of the common electrode CE may extend to the non-display area NDA, and may be connected to the first wiring layer BLI1 of the power bus line BLI.

The second wiring layer BLI2 may overlap at least a part of the first wiring layer BLI1. In one or more embodiments, the second wiring layer BLI2 may be located below the first wiring layer BLI1, and may be in contact with and/or connected to the first wiring layer BLI1.

In one or more embodiments, the second wiring layer BLI2 may have a width greater than that of the first wiring layer BLI1 in the first direction DR1. For example, the second wiring layer BLI2 may extend further toward an outer edge of the display panel 100 from a portion overlapping the first wiring layer BLI1, and may cover the scan driver (for example, the first scan driver SDC1 and the second scan driver SDC2 of FIGS. 2 and 3). In one or more embodiments, the second wiring layer BLI2 may be formed to include a plurality of openings OPN. Accordingly, gas generated by outgassing in the display panel 100 may be appropriately or suitably discharged.

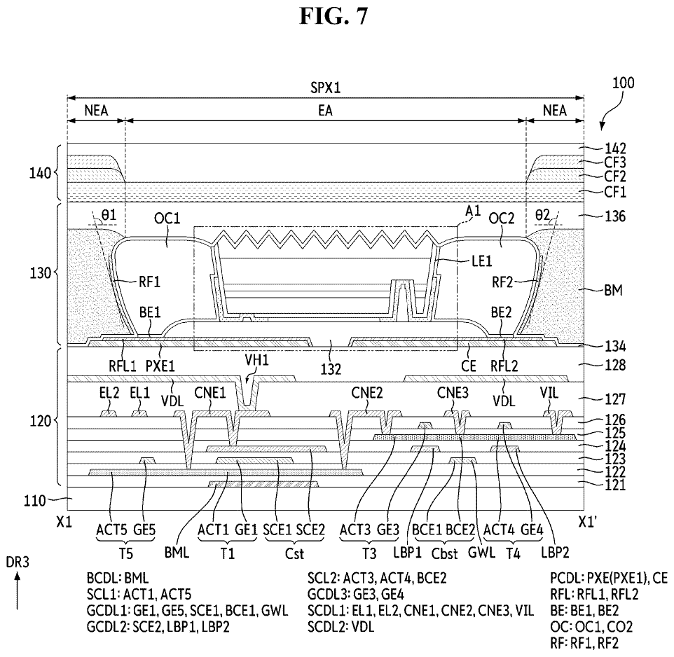

In one or more embodiments, the power bus line BLI may further include at least one wiring layer located in the backplane layer of the display panel 100. For example, the power bus line BLI may further include a third wiring layer located below the second wiring layer BLI2 and included in one of the conductive layers of the backplane layer (for example, a second source-drain conductive layer SCDL2 of FIG. 7). An end of the third wiring layer may be covered with at least one insulating layer. The at least one insulating layer may be opened in an area where the second wiring layer BLI2 (or the first wiring layer BLI1) and the third wiring layer overlap, thereby allowing the second wiring layer BLI2 and the third wiring layer to be in contact with and/or connected to each other. If the power bus line BLI does not include the second wiring layer BLI2, the third wiring layer may be in direct contact with and/or directly connected to the first wiring layer BLI1.

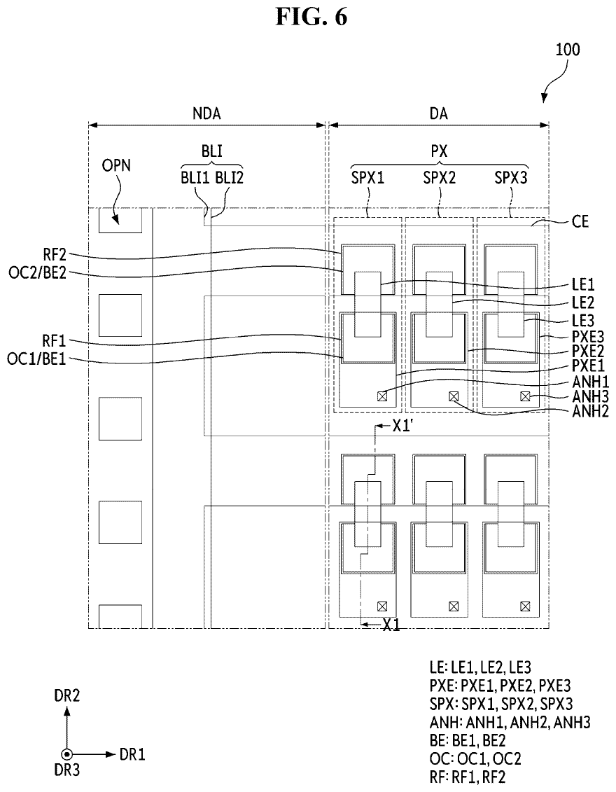

FIG. 6 is a plan view illustrating a display panel according to one or more embodiments. Compared to FIG. 5, FIG. 6 further shows connection electrodes BE, light transmitting patterns OC, and reflective films RF around (e.g., surrounding) the light emitting elements LE. In describing the following embodiments, parts that are substantially the same as or similar to those of at least one of the embodiments described above will be assigned the same reference numerals, and redundant descriptions thereof will not be provided.

Referring to FIGS. 5 and 6, the display panel 100 may further include the connection electrodes BE and the light transmitting patterns OC (or partition patterns) arranged in the sub-pixels SPX. In one or more embodiments, the display panel 100 may additionally include the reflective films RF.

The connection electrodes BE may include first connection electrodes BE1 and second connection electrodes BE2 that are spaced apart from each other. The first connection electrodes BE1 may be arranged on the pixel electrodes PXE of the sub-pixels SPX, and the second connection electrodes BE2 may be arranged on the common electrode CE of the sub-pixels SPX.

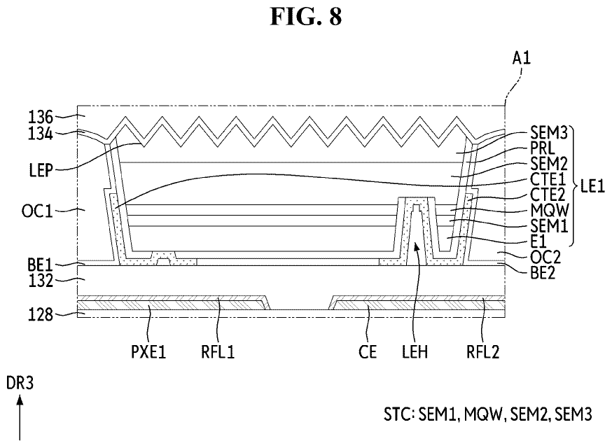

The first connection electrodes BE1 may connect the pixel electrode PXE of each of the sub-pixels SPX and the light emitting element LE. For example, in each of the sub-pixels SPX, the first connection electrode BE1 may electrically connect a portion of the light emitting element LE (for example, a portion including the first contact electrode CTE1 of FIG. 8) to the pixel electrode PXE. A portion of the first connection electrode BE1 may be directly in contact with or connected to a portion of the light emitting element LE, or may be electrically connected to a portion of the light emitting element LE through at least one other electrode and/or connection pattern. In one or more embodiments, another portion of the first connection electrode BE1 may be directly in contact with or connected to a portion of the pixel electrode PXE, or may be electrically connected to the pixel electrode PXE through at least one other electrode and/or connection pattern.

The second connection electrodes BE2 may connect the light emitting element LE and the common electrode CE of each of the sub-pixels SPX. For example, in each of the sub-pixels SPX, the second connection electrode BE2 may electrically connect another portion of the light emitting element LE (for example, a portion including the second contact electrode CTE2 of FIG. 8) to the common electrode CE. A portion of the second connection electrode BE2 may be directly in contact with or connected to another portion of the light emitting element LE, or may be electrically connected to another portion of the light emitting element LE through at least one other electrode and/or connection pattern. In one or more embodiments, another portion of the second connection electrode BE2 may be directly in contact with or connected to a portion of the common electrode CE, or may be electrically connected to the common electrode CE through at least one other electrode and/or connection pattern.

The light transmitting patterns OC may include first patterns OC1 and second patterns OC2 that are spaced apart from each other. The first patterns OC1 may be arranged on the pixel electrodes PXE of the sub-pixels SPX to overlap the first connection electrodes BE1, and the second patterns OC2 may be arranged on the common electrode CE of the sub-pixels SPX to overlap the second connection electrodes BE2. Each of the first patterns OC1 may also be referred to as “first light transmitting pattern” or “first barrier,” and each of the second patterns OC2 may also be referred to as “second light transmitting pattern” or “second barrier.”

The reflective films RF may include first reflective films RF1 and second reflective films RF2 that are spaced apart from each other. The first reflective films RF1 may surround the first connection electrodes BE1 and the first patterns OC1 of the sub-pixels SPX, and the second reflective films RF2 may surround the second connection electrodes BE2 and the second patterns OC2 of the sub-pixels SPX.

For example, each sub-pixel SPX may include the first connection electrode BE1 and the first pattern OC1 arranged on the pixel electrode PXE, the first reflective film RF1 around (e.g., surrounding) the side surfaces of the first connection electrode BE1 and the first pattern OC1, the second connection electrode BE2 and the second pattern OC2 arranged on the common electrode CE, and the second reflective film RF2 around (e.g., surrounding) the side surfaces of the second connection electrode BE2 and the second pattern OC2.

The first connection electrode BE1 and the first pattern OC1 may overlap each other in the third direction DR3, and may have mutually corresponding shapes. In one or more embodiments, the first connection electrode BE1 and the first pattern OC1 may have a shape that surrounds a portion of the light emitting element LE located on the pixel electrode PXE.

For example, the first connection electrode BE1 may be placed on a portion of the pixel electrode PXE so as to be in contact with a portion of the side surface of the light emitting element LE, which is located on the pixel electrode PXE, and surround a portion of the side surface of the light emitting element LE. The first pattern OC1 may be located on the first connection electrode BE1, and may have a shape and size corresponding to the first connection electrode BE1 when viewed from above at a plane formed by the intersecting first direction DR1 and second direction DR2 (e.g., in plan view). For example, the first connection electrode BE1 and the first pattern OC1 may be sequentially arranged on the pixel electrode PXE, and may have substantially the same shape and/or size in plan view.

The first reflective film RF1 may be located on the side surface of the first pattern OC1. Accordingly, the first reflective film RF1 may surround a portion of the side surface of the light emitting element LE surrounded by the first pattern OC1.

The second connection electrode BE2 and the second pattern OC2 may overlap each other in the third direction DR3, and may have mutually corresponding shapes. In one or more embodiments, the second connection electrode BE2 and the second pattern OC2 may have a shape that surrounds another portion of the light emitting element LE located on the common electrode CE.

For example, the second connection electrode BE2 may be arranged on a portion of the common electrode CE so as to be in contact with a portion of the side surface of the light emitting element LE located on the common electrode CE and surround a portion of the side surface of the light emitting element LE. The second pattern OC2 may be located on the second connection electrode BE2, and may have a shape and size corresponding to the second connection electrode BE2 when viewed from above (e.g., in plan view). For example, the second connection electrode BE2 and the second pattern OC2 may be sequentially arranged on the common electrode CE, and may have substantially the same planar shape and/or size.

The second reflective film RF2 may be located on the side surface of the second pattern OC2. Accordingly, the second reflective film RF2 may surround a portion of the side surface of the light emitting element LE surrounded by the second pattern OC2.

In describing the embodiments, a portion of the side surface of the light emitting element LE that is surrounded by the first connection electrode BE1, the first pattern OC1, and/or the first reflective film RF1 is referred to as “first side portion,” and another portion of the side surface of the light emitting element LE that is surrounded by the second connection electrode BE2, the second pattern OC2, and/or the second reflective film RF2 is referred to as “second side portion.” In one or more embodiments, the remaining portion of the side surface of the light emitting element LE other than the first side portion and the second side portion (for example, a side portion that is exposed without being surrounded by the first connection electrode BE1, the first pattern OC1, the first reflective film RF1, the second connection electrode BE2, the second pattern OC2, and/or the second reflective film RF2) is referred to as “third side portion.”

The first connection electrode BE1 and the second connection electrode BE2 of each sub-pixel SPX may be spaced apart from each other. By way of example, the first connection electrode BE1 and the second connection electrode BE2 may not be located in an area between the pixel electrode PXE and the common electrode CE, and may be spaced apart from each other in the second direction DR2. In this case, the first connection electrode BE1 and the second connection electrode BE2 may not be arranged on a portion of the light emitting element LE located in the area between the pixel electrode PXE and the common electrode CE, for example, on a portion of the light emitting element LE including the third side portion. For example, the first connection electrode BE1 and the second connection electrode BE2 may be spaced apart from each other while the third side portion of the light emitting element LE is interposed between the first connection electrode BE1 and the second connection electrode BE2.

In one or more embodiments, the first pattern OC1 and the second pattern OC2 of each sub-pixel SPX may be spaced apart from each other. For example, the first pattern OC1 and the second pattern OC2 may not be arranged in the area between the pixel electrode PXE and the common electrode CE, and may be spaced apart from each other in the second direction DR2. In this case, the first pattern OC1 and the second pattern OC2 may not be arranged on the portion of the light emitting element LE including the third side portion. By way of example, the first pattern OC1 and the second pattern OC2 may be spaced apart from each other while the third side portion of the light emitting element LE is interposed between the first pattern OC1 and the second pattern OC2.

In one or more embodiments, the first reflective film RF1 and the second reflective film RF2 may not be arranged on the portion of the light emitting element LE where the first pattern OC1 and the second pattern OC2 are not arranged. For example, the first reflective film RF1 and the second reflective film RF2 may not be arranged in the area between the pixel electrode PXE and the common electrode CE, and may be spaced apart from each other in the second direction DR2. By way of example, the first reflective film RF1 and the second reflective film RF2 may be spaced apart from each other while the third side portion of the light emitting element LE is interposed between the first reflective film RF1 and the second reflective film RF2.

In one or more embodiments, the light emitting element LE may have an approximately rectangular planar shape when viewed from above (e.g., in plan view), and may include four side surfaces that meet four corners of each of a top surface and a bottom surface. For example, the light emitting element LE may include a first side surface located on the pixel electrode PXE and extending in the first direction DR1 (for example, an upper side surface located at one end of the light emitting element LE in the second direction DR2 and positioned on the pixel electrode PXE), a second side surface located on the common electrode CE and extending in the first direction DR1 (for example, a lower side surface located at the other end of the light emitting element LE in the second direction DR2 and positioned on the common electrode CE), a third side surface connecting one end of the first side surface to one end of the second side surface and extending in the second direction DR2 (for example, a left side surface located at one end of the light emitting element LE in the first direction DR1), and a fourth side surface connecting the other end of the first side surface to the other end of the second side surface and extending in the second direction DR2 (for example, a right side surface located at the other end of the light emitting element LE in the first direction DR1).

In this case, the first side portion of the light emitting element LE may include the first side surface, a portion of the third side surface (for example, a portion of the third side surface located on the pixel electrode PXE), and a portion of the fourth side surface (for example, a portion of the fourth side surface located on the pixel electrode PXE) of the light emitting element LE. The second side portion of the light emitting element LE may include the second side surface, another portion of the third side surface (for example, a portion of the third side surface located on the common electrode CE), and another portion of the fourth side surface (for example, a portion of the fourth side surface located on the common electrode CE) of the light emitting element LE. The third side portion of the light emitting element LE may include the remaining portion of the third side surface (for example, a central portion of the third side surface located in the area between the pixel electrode PXE and the common electrode CE), and the remaining portion of the fourth side surface (for example, a central portion of the fourth side surface located in the area between the pixel electrode PXE and the common electrode CE) of the light emitting element LE.

In one or more embodiments, the display panel 100 may further include additional electrodes or configurations located in a light emitting element layer. For example, the display panel 100 may further include reflective electrodes RFL (see FIG. 7) located below the light emitting elements LE.

FIG. 7 is a cross-sectional view illustrating a display panel according to one or more embodiments. For example, FIG. 7 illustrates an example of a cross section of a portion of the display panel 100 corresponding to line X1-X1′ of FIG. 6.

FIG. 8 is a cross-sectional view showing area A1 of FIG. 7 in more detail. For example, FIG. 8 shows an example of the first light emitting element LE1 included in the first sub-pixel SPX1 in more detail. In one or more embodiments, the first light emitting element LE1, the second light emitting element LE2, and the third light emitting element LE3 of the first sub-pixel SPX1, the second sub-pixel SPX2, and the third sub-pixel SPX3 may have substantially the same or similar cross-sectional structure.

Referring to FIGS. 7 and 8 in addition to FIGS. 1 to 6, the display panel 100 may include a substrate 110, and a backplane layer 120 and a light emitting element layer 130 located on the substrate 110. In one or more embodiments, the display panel 100 may further include an optical layer 140 located on the light emitting element layer 130.

The substrate 110 may include an insulating material such as glass and/or polymer resin. When the substrate 110 includes polymer resin, it may be a flexible substrate that can be stretched.

The substrate 110 may include the display area DA and the non-display area NDA. The display area DA may include the emission areas EA of the sub-pixels SPX. Each emission area EA may include a light emitting element area where the light emitting element LE of each sub-pixel SPX is located. The display area DA may further include a non-emission area NEA located around the emission areas EA. The non-emission area NEA may surround the emission areas EA.

The backplane layer 120 may include circuit elements included in the pixel circuits PXC of the sub-pixels SPX and wires connected to the sub-pixels SPX. In one or more embodiments, the backplane layer 120 may be formed entirely on one surface of the substrate 110.

The backplane layer 120 may include at least one semiconductor layer, conductive layers, and/or insulating layers. In one or more embodiments, when the pixel circuits PXC include at least two types (kinds) of pixel transistors PXT containing different materials, the backplane layer 120 may include a plurality of semiconductor layers.

For example, the backplane layer 120 may include a lower conductive layer BCDL, a barrier layer 121 (or a buffer layer), a first semiconductor layer SCL1 (e.g., a polycrystalline silicon semiconductor layer), a first insulating layer 122 (e.g., a first inorganic insulating layer), a first gate conductive layer GCDL1 (or a first conductive layer), a second insulating layer 123 (e.g., a second inorganic insulating layer), a second gate conductive layer GCDL2 (or a second conductive layer), a third insulating layer 124 (e.g., a third inorganic insulating layer), a second semiconductor layer SCL2 (e.g., an oxide semiconductor layer), a fourth insulating layer 125 (e.g., a fourth inorganic insulating layer), a third gate conductive layer GCDL3 (or a third conductive layer), a fifth insulating layer 126 (e.g., a fifth inorganic insulating layer), a first source-drain conductive layer SCDL1 (or a fourth conductive layer), a sixth insulating layer 127 (e.g., a first organic insulating layer), the second source-drain conductive layer SCDL2 (or a fifth conductive layer), and a seventh insulating layer 128 (e.g., a second organic insulating layer) that are sequentially located on the substrate 110 along the third direction DR3.

The lower conductive layer BCDL may include a lower conductive pattern BML located below the first transistor T1. The lower conductive pattern BML may entirely or partially cover the bottom surface of the first active layer ACT1 included in the first transistor T1. For example, the lower conductive pattern BML may be located below the first active layer ACT1 to overlap a channel region (e.g., a portion of the first active layer ACT1 overlapping the first gate electrode GE1) of the first active layer ACT1. In one or more embodiments, the lower conductive layer BCDL may include a light blocking material such as metal. Accordingly, light may be prevented or reduced from being incident on the channel region of the first active layer ACT1 from the bottom of the first active layer ACT1, and the operating characteristics of the first transistor T1 may be stabilized or improved.

The barrier layer 121 may be located on the lower conductive layer BCDL. The barrier layer 121 may protect the circuit elements of the backplane layer 120 and the light emitting elements LE on the backplane layer 120 from moisture permeating through the substrate 110 that is susceptible to moisture permeation. In one or more embodiments, the barrier layer 121 may be formed as a plurality of inorganic insulating layers.

The circuit elements of the backplane layer 120 may be located on the barrier layer 121. For example, the pixel transistors PXT, the storage capacitor Cst, and the boosting capacitor Cbst included in the pixel circuit PXC of each of the sub-pixels SPX may be located on the barrier layer 121. Additionally, wires of the backplane layer 120 may be located on the barrier layer 121. For example, signal lines and power lines electrically connected to the sub-pixels SPX may be located on the barrier layer 121.

FIG. 7 shows, as an example of the circuit elements included in the backplane layer 120, the first transistor T1, the third transistor T3, the fourth transistor T4, the fifth transistor T5, the storage capacitor Cst, and the boosting capacitor Cbst that are included in the first sub-pixel SPX1. Further, FIG. 7 shows, as an example of wires included in the backplane layer 120, the write scan line GWL, the first and second emission control lines EL1 and EL2, the first power line VDL, and the third power line VIL. Each of other wires may include at least one wiring layer included in at least one conductive layer included in the backplane layer 120, and may be formed as a single-layer or multi-layer wire.

In one or more embodiments, each of the pixel circuits PXC may include first type transistors and second type transistors. The first type transistors and the second type transistors may be located in different layers within the backplane layer 120. For example, as shown in FIG. 4, each of the pixel circuits PXC may include the first, second, fifth, sixth, seventh, and eighth P-type transistors T1, T2, T5, T6, T7, and T8 and the third and fourth N-type transistors T3 and T4. The active layers included in the first, second, fifth, sixth, seventh and eighth transistors T1, T2, T5, T6, T7, and T8 and the active layers included in the third and fourth transistors T3 and T4 may be formed in patterns of different semiconductor layers. Further, the gate electrodes included in the first, second, fifth, sixth, seventh and eighth transistors T1, T2, T5, T6, T7, and T8 and the gate electrodes included in the third and fourth transistors T3 and T4 may be formed in patterns of different conductive layers.

The first semiconductor layer SCL1 (also referred to as “first semiconductor pattern layer”) may be located on the barrier layer 121. The first semiconductor layer SCL1 may include an active layer of each of the first type transistors. For example, the first semiconductor layer SCL1 may include the first active layer ACT1 included in the first transistor T1, a fifth active layer ACT5 included in the fifth transistor T5, and second, sixth, seventh, and eighth active layers included in the second, sixth, seventh, and eighth transistors T2, T6, T7, and T8. In one or more embodiments, the patterns (for example, the first and fifth active layers ACT1 and ACT5 and the second, sixth, seventh, and eighth active layers of each sub-pixel SPX) of the first semiconductor layer SCL1 included in one sub-pixel SPX may be formed integrally, but the present disclosure is not limited thereto.

The patterns of the first semiconductor layer SCL1 may include a first semiconductor material. In one or more embodiments, the first semiconductor material may be polycrystalline silicon (e.g., low temperature polycrystalline silicon), but the present disclosure is not limited thereto. For example, the first semiconductor material may be an oxide semiconductor (e.g., at least one selected from among zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), and indium-tin-gallium-zinc oxide (ITGZO), and/or another suitable oxide semiconductor) and/or single crystal silicon.

The first insulating layer 122 may be located on the first semiconductor layer SCL1. The first insulating layer 122 may include at least one insulating material (e.g., silicon nitride (SiNx, e.g., Si₃N₄), silicon oxide (SiOx, e.g., SiO₂), silicon oxynitride (SiOxNy, e.g., SiON), titanium oxide (TiOx, e.g., TiO₂), aluminum oxide (AlOx, e.g., Al₂O₃), and/or another suitable inorganic insulating material) and may be formed as a single layer or multiple layers.

The first gate conductive layer GCDL1 may be located on the first insulating layer 122. The first gate conductive layer GCDL1 may include a gate electrode of each of the first type transistors. For example, the first gate conductive layer GCDL1 may include the first gate electrode GE1 included in the first transistor T1, a fifth gate electrode GE5 included in the fifth transistor T5, and second, sixth, seventh, and eighth gate electrodes included in the second, sixth, seventh, and eighth transistors T2, T6, T7, and T8.

The first gate conductive layer GCDL1 may further include at least one conductive pattern and/or wire. For example, the first gate conductive layer GCDL1 may further include a first capacitor electrode SCE1 of the storage capacitor Cst, a first electrode BCE1 of the boosting capacitor Cbst, and the write scan line GWL. In one or more embodiments, the first gate electrode GE1 of each pixel circuit PXC and the first capacitor electrode SCE1 of the storage capacitor Cst may be formed integrally, and the first electrode BCE1 of the boosting capacitor Cbst of each pixel circuit PXC and the write scan line GWL connected to the pixel circuit PXC may be formed integrally.

The second insulating layer 123 may be located on the first gate conductive layer GCDL1. The second insulating layer 123 may contain at least one insulating material (e.g., an inorganic insulating material) and may be formed as a single layer or multiple layers.

The second gate conductive layer GCDL2 may be located on the second insulating layer 123. The second gate conductive layer GCDL2 may include the second capacitor electrode SCE2 of the storage capacitor Cst. The first capacitor electrode SCE1 and the second capacitor electrode SCE2 of the storage capacitor Cst may overlap each other while the second insulating layer 123 is interposed between the first capacitor electrode SCE1 and the second capacitor electrode SCE2.

The second gate conductive layer GCDL2 may further include at least one conductive pattern and/or wire. For example, the second gate conductive layer GCDL2 may further include a first blocking pattern LBP1 and a second blocking pattern LBP2. The first blocking pattern LBP1 and the second blocking pattern LBP2 may be respectively located under a channel region of a third active layer ACT3 (for example, a part of the third active layer ACT3 that overlaps the third gate electrode GE3), and a channel region of a fourth active layer ACT4 (for example, a part of the fourth active layer ACT4 that overlaps the fourth gate electrode GE4). Accordingly, light incident on the channel regions of the third active layer ACT3 and the fourth active layer ACT4 from the bottom of the third active layer ACT3 and the fourth active layer ACT4 may be blocked or reduced, and the operating characteristics of the third transistor T3 and the fourth transistor T4 may be stabilized or improved.

The third insulating layer 124 may be located on the second gate conductive layer GCDL2. The third insulating layer 124 may contain at least one insulating material (e.g., an inorganic insulating material) and may be formed as a single layer or multiple layers.

The second semiconductor layer SCL2 (also referred to as “second semiconductor pattern layer”) may be located on the third insulating layer 124. The second semiconductor layer SCL2 may include the active layer of each of the second type transistors. For example, the second semiconductor layer SCL2 may include the third active layer ACT3 included in the third transistor T3 and the fourth active layer ACT4 included in the fourth transistor T4. In one or more embodiments, the patterns (for example, the third and fourth active layers ACT3 and ACT4 of each sub-pixel SPX) of the second semiconductor layer SCL2 included in one sub-pixel SPX may be formed integrally, but the present disclosure is not limited thereto. In one or more embodiments, the second semiconductor layer SCL2 may further include the second electrode BCE2 of the boosting capacitor Cbst, and the second electrode BCE2 of the boosting capacitor Cbst may be integrally formed with the third and fourth active layers ACT3 and ACT4.

The patterns of the second semiconductor layer SCL2 may include a second semiconductor material. In one or more embodiments, the second semiconductor material may be an oxide semiconductor, but the present disclosure is not limited thereto. For example, the second semiconductor material may be polycrystalline silicon and/or single crystal silicon.

The fourth insulating layer 125 may be located on the second semiconductor layer SCL2. The fourth insulating layer 125 may contain at least one insulating material (e.g., an inorganic insulating material) and may be formed as a single layer or multiple layers.

The third gate conductive layer GCDL3 may be located on the fourth insulating layer 125. The third gate conductive layer GCDL3 may include a gate electrode of each of the second type transistors. For example, the third gate conductive layer GCDL3 may include the third gate electrode GE3 included in the third transistor T3 and the fourth gate electrode GE4 included in the fourth transistor T4.

The fifth insulating layer 126 may be located on the third gate conductive layer GCDL3. The fifth insulating layer 126 may contain at least one insulating material (e.g., an inorganic insulating material) and may be formed as a single layer or multiple layers.

The first source-drain conductive layer SCDL1 may be located on the fifth insulating layer 126. The first source-drain conductive layer SCDL1 may include at least one electrode, a conductive pattern and/or a wire. For example, the first source-drain conductive layer SCDL1 may include first, second, and third connection patterns CNE1, CNE2, and CNE3, the first and second emission control lines EL1 and EL2, and the third power line VIL.

The first connection pattern CNE1 may be electrically connected to the fifth active layer ACT5, the second capacitor electrode SCE2 of the storage capacitor Cst, and the first power line VDL through at least one contact hole or via hole. The second connection pattern CNE2 may be electrically connected to the first active layer ACT1 and the third active layer ACT3 through at least one contact hole. The third connection pattern CNE3 may be electrically connected to the third active layer ACT3 and the fourth active layer ACT4 through at least one contact hole. The third connection pattern CNE3 may be electrically connected to the first gate electrode GE1 and the first capacitor electrode SCE1 of the storage capacitor Cst through at least one contact hole. In one or more embodiments, the first source-drain conductive layer SCDL1 may further include an additional connection pattern for appropriately or suitably connecting the circuit elements of each sub-pixel SPX.

The first emission control line EL1 may be electrically connected to the fifth gate electrode GE5 and the sixth gate electrode of the first sub-pixel SPX1 through at least one contact hole. The second emission control line EL2 may be electrically connected to the fifth and sixth gate electrodes of the second and third sub-pixels SPX2 and SPX3 through at least one contact hole. The third power line VIL may be electrically connected to the fourth active layer ACT4 through at least one contact hole.

The sixth insulating layer 127 may be located on the first source-drain conductive layer SCDL1. The sixth insulating layer 127 may include at least one insulating material (e.g., acrylic resin, epoxy resin, phenolic resin, polyamide resin, polyimide resin, and/or another suitable organic insulating material) and may be formed as a single layer or multiple layers.

The second source-drain conductive layer SCDL2 may be located on the sixth insulating layer 127. The second source-drain conductive layer SCDL2 may include at least one electrode, a conductive pattern and/or a wire. For example, the second source-drain conductive layer SCDL2 may include the first power line VDL.

In one or more embodiments, the first power line VDL may extend substantially in the second direction DR2 in the display area DA, and may be commonly connected to the sub-pixels SPX arranged continuously and/or sequentially in the second direction DR2. The first power line VDL illustrated as two separated patterns in FIG. 7 may be substantially one integral wire. The first power line VDL may be electrically connected to the first connection pattern CNE1 through the first via hole VH1 (or contact hole). The first via hole VH1, which is an opening formed in the sixth insulating layer 127 for contact between the first connection pattern CNE1 and the first power line VDL, may be a type or kind of contact hole. In one or more embodiments, the first power line VDL may overlap the channel regions of the first active layer ACT1, the third active layer ACT3, and the fourth active layer ACT4. Accordingly, light incident on the channel regions of the first active layer ACT1, the third active layer ACT3, and the fourth active layer ACT4 from the top of the first active layer ACT1, the third active layer ACT3, and the fourth active layer ACT4 may be prevented or reduced, and the operating characteristics of the first transistor T1, the third transistor T3, and the fourth transistor T4 may be stabilized or improved.

In one or more embodiments, the second source-drain conductive layer SCDL2 may further include an anode connection pattern connected to the pixel electrode PXE of each of the sub-pixels SPX, and data lines DL of FIGS. 3 and 4. The anode connection pattern of each sub-pixel SPX may be electrically connected between the pixel electrode PXE and the pixel circuit PXC of the corresponding sub-pixel SPX. For example, the anode connection pattern of each sub-pixel SPX may be electrically connected to the sixth and seventh active layers of the corresponding sub-pixel SPX through at least one contact hole and/or at least one connection pattern, and may be electrically connected to the pixel electrode PXE of the corresponding sub-pixel SPX through the anode contact hole ANH of FIG. 6.

The seventh insulating layer 128 may be located on the second source-drain conductive layer SCDL2. The seventh insulating layer 128 may contain at least one insulating material (e.g., an organic insulating material) and may be formed as a single layer or multiple layers.

The patterns included in each of the conductive layers of the backplane layer 120 may contain at least one conductive material. For example, the electrodes, the conductive patterns, and/or the wires included in each of the lower conductive layer BCDL, the first gate conductive layer GCDL1, the second gate conductive layer GCDL2, the third gate conductive layer GCDL3, the first source-drain conductive layer SCDL1 and the second source-drain conductive layer SCDL2 may include at least one selected from among copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), another suitable metal, an alloy thereof, and/or another suitable conductive material. In one or more embodiments, the electrodes, the conductive patterns, and/or the wires located in substantially the same conductive layer may be concurrently (e.g., simultaneously) formed using the same conductive material. The patterns included in each of the conductive layers of the backplane layer 120 may have a single-layer or multi-layer structure.

The light emitting element layer 130 may be located on the seventh insulating layer 128. The light emitting element layer 130 may include the pixel electrodes PXE, the common electrode CE, the light emitting elements LE, the first connection electrodes BE1, and the second connection electrodes BE2 included in the sub-pixels SPX. In one or more embodiments, the light emitting element layer 130 may further include at least one selected from among the reflective electrodes RFL, the light transmitting patterns OC, the reflective films RF, and a light blocking layer BM.

In one or more embodiments, the light emitting element layer 130 may further include plurality of insulating layers. In one or more embodiments, the insulating layers of the light emitting element layer 130 may include an eighth insulating layer 132, a ninth insulating layer 134, and a first overcoat layer 136.

For example, a pixel electrode layer PCDL including the pixel electrodes PXE of the sub-pixels SPX may be located on the seventh insulating layer 128. For example, the pixel electrode layer PCDL may include the first pixel electrode PXE1, the second pixel electrode PXE2, and the third pixel electrode PXE3. In one or more embodiments, the light emitting element LE may be a flip-chip type or kind micro LED. The flip-chip type or kind micro LED refers to an LED in which first and second contact electrodes CTE1 and CTE2 are formed on one surface (e.g., the bottom surface) of the light emitting element LE. When the light emitting element LE is a flip-chip type or kind micro LED, the pixel electrode layer PCDL may further include the common electrode CE. For example, the pixel electrodes PXE and the common electrode CE of the sub-pixels SPX may be located in substantially the same layer and may be concurrently (e.g., simultaneously) formed using the same conductive material. FIG. 7 illustrates the common electrode CE and the first pixel electrode PXE1 of the first sub-pixel SPX1 among the patterns of the pixel electrode layer PCDL.

The first pixel electrode PXE1 of the first sub-pixel SPX1 may be electrically connected to the pixel circuit PXC of the first sub-pixel SPX1 through the first anode contact hole ANH1 of FIG. 6. The second pixel electrode PXE2 of the second sub-pixel SPX2 may be electrically connected to the pixel circuit PXC of the second sub-pixel SPX2 through the second anode contact hole ANH2 of FIG. 6. The third pixel electrode PXE3 of the third sub-pixel SPX3 may be electrically connected to the pixel circuit PXC of the third sub-pixel SPX3 through the third anode contact hole ANH3 in FIG. 6.

The patterns of the pixel electrode layer PCDL, for example, the pixel electrodes PXE and the common electrode CE may include at least one conductive material, and may be formed as a single layer or multiple layers. In one or more embodiments, the patterns of the pixel electrode layer PCDL may include metal (e.g., at least one selected from among molybdenum (Mo), aluminum (Al), chromium (Cr), gold (Au), titanium (Ti), nickel (Ni), neodymium (Nd), copper (Cu), and another suitable metal, and/or an alloy thereof) and may have a single-layer or multi-layer structure. For example, the patterns of the pixel electrode layer PCDL may be low-resistance patterns formed in a three-layer structure (Ti/Al/Ti) of titanium (Ti), aluminum (Al), and titanium (Ti). In some embodiments, the patterns of the pixel electrode layer PCDL may include other low-resistance materials (e.g., copper (Cu)) and/or structures. When the resistance of the patterns included in the pixel electrode layer PCDL is reduced or minimized, the first driving voltage VDD and the second driving voltage VSS may be stably or suitably transmitted to the light emitting elements LE of the sub-pixels SPX.

In one or more embodiments, the reflective electrodes RFL may be arranged on the pixel electrode layer PCDL. For example, each sub-pixel SPX may include a first reflective electrode RFL1 located on the pixel electrode PXE, and a second reflective electrode RFL2 located on the common electrode CE.

The first reflective electrode RFL1 may cover at least a part of the pixel electrode PXE. By way of example, the first reflective electrode RFL1 may be located on a portion of the pixel electrode PXE including an end portion overlapping the light emitting element LE.

The second reflective electrode RFL2 may cover at least a part of the common electrode CE. For example, the second reflective electrode RFL2 may be located on a portion of the common electrode CE including an end portion overlapping the light emitting element LE.

The reflective electrodes RFL may include a material having suitably high reflectivity for the light emitted from the light emitting element LE. In one or more embodiments, each of the reflective electrodes RFL may be a single-layer or multi-layer conductive pattern including a conductive material. For example, the reflective electrodes RFL may include silver (Ag) and/or aluminum (Al), or may include other metals having suitably high light reflectivity. For example, the reflective electrodes RFL may be formed in a three-layer structure (ITO/Ag/ITO) of indium-tin oxide (ITO), silver (Ag), and indium-tin oxide (ITO).

When the first reflective electrode RFL1 and the second reflective electrode RFL2 have conductivity, the pixel electrode PXE may be electrically connected to a portion of the light emitting element LE through the first reflective electrode RFL1 and the first connection electrode BE1, and the common electrode CE may be electrically connected to another portion of the light emitting element LE through the second reflective electrode RFL2 and the second connection electrode BE2.

In FIG. 7, the pixel electrode PXE, the common electrode CE, the first reflective electrode RFL1, and the second reflective electrode RFL2 are illustrated as separate parts, but the embodiments are not limited thereto. For example, the first reflective electrode RFL1 may be a part of the pixel electrode PXE, and the second reflective electrode RFL2 may be a part of the common electrode CE. For example, the pixel electrode PXE may be formed as a single-layer or multi-layer electrode including the first reflective electrode RFL1, and the common electrode CE may be formed as a single-layer or multi-layer electrode including the second reflective electrode RFL2. In some embodiments, the display panel 100 may not include (e.g., may exclude) the first reflective electrode RFL1 and the second reflective electrode RFL2 of FIG. 7, and the eighth insulating layer 132, the first connection electrode BE1, and the second connection electrode BE2 may be directly placed on the pixel electrode layer PCDL. In one or more embodiments, the display panel 100 may not additionally include the first reflective electrode RFL1 and the second reflective electrode RFL2, and instead the pixel electrode PXE and the common electrode CE may include a material having suitably high reflectivity, thereby functioning as reflective layers.

The eighth insulating layer 132 may be located on the pixel electrode layer PCDL and the reflective electrodes RFL. The eighth insulating layer 132 may be an adhesive layer that temporarily fixes and/or adheres the light emitting elements LE to prevent or reduce the tilting and falling over or tipping over of the light emitting elements LE during the process of transferring the light emitting elements LE to the display panel 100. For example, the eighth insulating layer 132 may be a film for temporarily adhering the light emitting elements LE onto each of the pixel electrodes PXE and the common electrode CE. To facilitate temporary adhesion, the thickness of the eighth insulating layer 132 may be greater than the thickness of each of the pixel electrodes PXE and the common electrode CE, and may be greater than the thickness of each of the first and second contact electrodes CTE1 and CTE2 of the light emitting elements LE. The eighth insulating layer 132 may also be referred to as “adhesive layer” or “bonding layer.”

The eighth insulating layer 132 may partially cover the pixel electrode PXE, the common electrode CE, the first reflective electrode RFL1, and the second reflective electrode RFL2 under the light emitting element LE. In one or more embodiments, the eighth insulating layer 132 may be located only in a portion of the emission area EA including the area where each light emitting element LE is located. For example, the eighth insulating layer 132 may be separately located within the emission area EA of each of the sub-pixels SPX. However, the embodiments are not limited thereto. For example, in some embodiments, the eighth insulating layer 132 may be located entirely across the display area DA or across the respective sub-pixel areas or emission areas EA. In this case, connection holes may be formed in the eighth insulating layer 132 to expose a portion of the top surface of each of the first reflective electrode RFL1 and the second reflective electrode RFL2 (or a portion of the top surface of each of the pixel electrode PXE and the common electrode CE), and the first connection electrode BE1 and the second connection electrode BE2 may be in contact with and/or connected to the first reflective electrode RFL1 and the second reflective electrode RFL2 (or the pixel electrode PXE and the common electrode CE), respectively, through these connection holes.

The eighth insulating layer 132 may include at least one insulating material, for example, an organic insulating material. For example, the eighth insulating layer 132 may be a photosensitive organic layer such as a photoresist. In one or more embodiments, the eighth insulating layer 132 may include acrylic resin, epoxy resin, phenolic resin, polyamide resin, polyimide resin, and/or the like.

In FIG. 7, the eighth insulating layer 132 is depicted as having a substantially uniform thickness or height overall and being substantially flat under and around the light emitting element LE, but the embodiments are not limited thereto. For example, when the eighth insulating layer 132 is pressed by a pressure applied in the process of arranging the light emitting elements LE on the eighth insulating layer 132, the height of the eighth insulating layer 132 may partially decrease at the portions where the light emitting elements LE are located.

The light emitting elements LE may be located on the eighth insulating layer 132. In one or more embodiments, each of the light emitting elements LE may be a micro LED including an inorganic material. For example, each of the light emitting elements LE may include an inorganic material such as gallium nitride (GaN), and the length in the first direction DR1, the length in the second direction DR2, and the length in the third direction DR3 of each of the light emitting elements LE may each be several μm to several hundred μm. For example, the length in the first direction DR1, the length in the second direction DR2, and the length in the third direction DR3 of each of the light emitting elements LE may each be approximately 100 μm or less.

The light emitting elements LE may be formed by growing on a semiconductor substrate such as a silicon substrate and/or sapphire substrate. The light emitting elements LE may be transferred directly from the semiconductor substrate onto the pixel electrodes PXE and the common electrode CE of the display panel 100. In some embodiments, the light emitting elements LE may be transferred onto the common electrode CE and the pixel electrodes PXE of the display panel 100 through an electrostatic method using an electrostatic head and/or a stamping method using an elastic polymer material such as PDMS and/or silicon as a transfer substrate.

The light emitting element LE may include a conductive layer E1, a semiconductor stack STC, the first and second contact electrodes CTE1 and CTE2, and a protective film PRL. The semiconductor stack STC may include a first semiconductor layer SEM1, an active layer MQW (e.g., light emitting layer), and a second semiconductor layer SEM2 sequentially located in the third direction DR3. In one or more embodiments, the semiconductor stack STC may optionally further include a third semiconductor layer SEM3 located on the second semiconductor layer SEM2.

The conductive layer E1 may be located on the bottom surface of the first semiconductor layer SEM1. FIG. 8 illustrates that the conductive layer E1 covers the entire bottom surface of the first semiconductor layer SEM1, but the embodiments are not limited thereto. For example, the conductive layer E1 may be located on a portion of the bottom surface of the first semiconductor layer SEM1. The conductive layer E1 may include one selected from among molybdenum (Mo), aluminum (Al), chromium (Cr), gold (Au), titanium (Ti), nickel (Ni), neodymium (Nd), and copper (Cu), and/or a transparent conductive material such as metal oxide.

The first semiconductor layer SEM1 may be located on the conductive layer E1. The first semiconductor layer SEM1 may be formed as a semiconductor material layer doped with a first conductivity type or kind dopant such as magnesium (Mg), zinc (Zn), calcium (Ca), strontium (Sr), and/or barium (Ba), for example, gallium nitride (GaN).

The active layer MQW may be located on the first semiconductor layer SEM1. The active layer MQW may include the same semiconductor material as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include at least one selected from among gallium nitride (GaN), indium gallium nitride (InGaN), and aluminum gallium nitride (AlGaN). The active layer MQW may be to emit light by recombination of electron-hole pairs according to an electrical signal applied through the first semiconductor layer SEM1 and the second semiconductor layer SEM2.

The active layer MQW may include a material having a single or multiple quantum well structure. When the active layer MQW contains a material having a multiple quantum well structure, the active layer MQW may have the structure in which a plurality of well layers and barrier layers are alternately stacked. For example, the well layer may include InGaN, and the barrier layer may include GaN and/or AlGaN, but the present disclosure is not limited thereto. In one or more embodiments, the active layer MQW may have a structure in which semiconductor materials having large band gap energy and semiconductor materials having small band gap energy are alternately stacked, and may include other group III to V semiconductor materials according to the wavelength band of the emitted light.

When the active layer MQW includes indium gallium nitride (InGaN), the color of emitted light may vary depending on the content (e.g., amount) of indium (In). For example, as the content (e.g., amount) of indium (In) increases, the wavelength band of the light emitted by the active layer MQW may shift to the red wavelength band, and as the content (e.g., amount) of indium (In) decreases, the wavelength band of the light emitted by the active layer MQW may shift to the blue wavelength band.

The second semiconductor layer SEM2 may be located on the active layer MQW. The second semiconductor layer SEM2 may be a semiconductor material layer doped with a second conductivity type or kind dopant such as silicon (Si), germanium (Ge), and/or tin (Sn), for example, gallium nitride (GaN).

The third semiconductor layer SEM3 may be located on the second semiconductor layer SEM2. The third semiconductor layer SEM3 may be a semiconductor material layer having an n-type dopant in an amount lower than a selected critical value, and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) having an n-type dopant in an amount lower than a selected threshold value. In some embodiments, the third semiconductor layer SEM3 may not be provided.

An electron blocking layer may be located between the first semiconductor layer SEM1 and the active layer MQW. The electron blocking layer may be a layer for suppressing, preventing, or reducing too many electrons from flowing into the active layer MQW. For example, the electron blocking layer may be AlGaN and/or p-AlGaN doped with p-type Mg. In some embodiments, the electron blocking layer may not be provided.

A superlattice layer may be located between the active layer MQW and the second semiconductor layer SEM2. The superlattice layer may be a layer for relieving stress between the second semiconductor layer SEM2 and the active layer MQW. For example, the superlattice layer may include InGaN and/or GaN. In some embodiments, the superlattice layer may not be provided.

The protective film PRL may be located on the side surfaces of the conductive layer E1 and the semiconductor stack STC. The protective film PRL may include an inorganic material, for example, silicon nitride (SiNx, e.g., Si₃N₄), silicon oxide (SiOx, e.g., SiO₂), silicon oxynitride (SiOxNy, e.g., SiON), titanium oxide (TiOx, e.g., TiO₂), aluminum oxide (AlOx, e.g., Al₂O₃), and/or another suitable inorganic insulating material.

A hole LEH that penetrates the conductive layer E1, the first semiconductor layer SEM1, and the active layer MQW of the light emitting element LE to expose the second semiconductor layer SEM2 may be formed. The hole LEH may have a circular planar shape as shown in FIG. 2, but the shape of the hole LEH is not limited thereto. For example, the hole LEH may have a planar shape such as an elliptical shape or a polygonal shape, such as a quadrilateral shape.

The protective film PRL may be located on the sidewall of the conductive layer E1 exposed in the hole LEH, the sidewall of the first semiconductor layer SEM1, and the sidewall of the active layer MQW. The protective film PRL may not cover the second semiconductor layer SEM2 at (e.g., inside) the hole LEH.

The first contact electrode CTE1 may be located on at least one side surface of the semiconductor stack STC and at least one side surface and the bottom surface of the conductive layer E1. For example, the first contact electrode CTE1 may be located on the first side portion and a portion of the bottom surface of the light emitting element LE. For example, the first contact electrode CTE1 may be located on the first side surface, a portion of the third side surface, and a portion of the fourth side surface of each of the semiconductor stack STC and the conductive layer E1 (e.g., of the light emitting element LE), and on a portion of the bottom surface of the conductive layer E1. The first contact electrode CTE1 may not be located on the second side portion and the third side portion of the light emitting element LE.

The bottom surface of the conductive layer E1 may include, at its portion overlapping the first contact electrode CTE1, a portion that is exposed without being covered with the protective film PRL. The first contact electrode CTE1 may be located on a portion of the bottom surface of the conductive layer E1 that is not covered with the protective film PRL, and may be electrically connected to the conductive layer E1.

The second contact electrode CTE2 may be located on at least one side surface of the semiconductor stack STC and at least one side surface and the bottom surface of the conductive layer E1. For example, the second contact electrode CTE2 may be located on the second side portion and another portion of the bottom surface of the light emitting element LE. For example, the second contact electrode CTE2 may be located on the second side surface, another portion of the third side surface, and another portion of the fourth side surface of each of the semiconductor stack STC and the conductive layer E1 (e.g., of the light emitting element LE), and on another portion of the bottom surface of the conductive layer E1. The second contact electrode CTE2 may not be located on the first side portion and the third side portion of the light emitting element LE.

The second contact electrode CTE2 may be located on the protective film PRL located in the hole LEH and the second semiconductor layer SEM2 exposed without being covered by the protective film PRL in the hole LEH. The second contact electrode CTE2 may be electrically connected to the second semiconductor layer SEM2 in the hole LEH.

Each of the first contact electrode CTE1 and the second contact electrode CTE2 may include at least one conductive material, for example, one selected from among molybdenum (Mo), aluminum (Al), chromium (Cr), gold (Au), titanium (Ti), nickel (Ni), neodymium (Nd), and copper (Cu). In one or more embodiments, in order to increase the reflectivity, the first contact electrode CTE1 and the second contact electrode CTE2 may be formed in a two-layer structure (Cr/Au) of chromium (Cr) and gold (Au), a three-layer structure (Ti/Al/Ti) of titanium (Ti), aluminum (Al), and titanium (Ti), or a three-layer structure (ITO/Ag/ITO) of indium-tin oxide (ITO), silver (Ag), and indium-tin oxide (ITO).

When each of the first contact electrode CTE1 and the second contact electrode CTE2 includes metal having suitably high reflectivity, light emitted from the active layer MQW of the light emitting element LE, which propagates in the lateral direction of the light emitting element LE, may be reflected by the first contact electrode CTE1 and the second contact electrode CTE2 and emitted to the top surface of the light emitting element LE. Therefore, the light loss of the light emitting element LE may be reduced, whereas the light efficiency of the light emitting element LE may be increased. In order to enhance the light efficiency of the light emitting element LE, the first contact electrode CTE1 and the second contact electrode CTE2 may be arranged to cover at least the side surface of the active layer MQW.

In one or more embodiments, the light emitting element LE may include light extraction patterns LEP formed on its one surface from which light is emitted. For example, the light emitting element LE may include the light extraction patterns LEP formed on the top surface of the semiconductor stack STC (for example, the top surface of the third semiconductor layer SEM3). The light extraction patterns LEP may have a shape suitable for diffusing and/or scattering light on the top surface of the light emitting element LE. For example, the top surface of the light emitting element LE may be formed non-flat so that the top surface of the light emitting element LE has a shape suitable for light scattering. Accordingly, the light efficiency of the light emitting element LE (for example, the light emission rate of light generated from the light emitting element LE) may be increased.

In one or more embodiments, the light emitting element LE may include side surfaces having a reverse tapered shape. For example, the light emitting element LE may have a shape with its width and/or area gradually increasing as it goes from the bottom to the top. Accordingly, the amount of the light emitted from the top surface of the light emitting element LE may be increased, so that the light efficiency of the light emitting element LE may be further enhanced.

The connection electrodes BE may be arranged on the eighth insulating layer 132. For example, the first connection electrode BE1 and the second connection electrode BE2 may be arranged on different portions of the eighth insulating layer 132. The first connection electrode BE1 and the second connection electrode BE2 may be spaced apart from each other while the light emitting element LE is interposed between the first connection electrode BE1 and the second connection electrode BE2.

The first connection electrode BE1 connects the first contact electrode CTE1 of the light emitting element LE to the pixel electrode PXE. For example, the first connection electrode BE1 of the first sub-pixel SPX1 may electrically connect the first contact electrode CTE1 of the first light emitting element LE1 to the first pixel electrode PXE1. The first connection electrode BE1 of the second sub-pixel SPX2 may electrically connect the first contact electrode CTE1 of the second light emitting element LE2 to the second pixel electrode PXE2. The first connection electrode BE1 of the third sub-pixel SPX3 may electrically connect the first contact electrode CTE1 of the third light emitting element LE3 to the third pixel electrode PXE3.

In one or more embodiments, the first connection electrode BE1 may be in contact with the first contact electrode CTE1 of the light emitting element LE on the eighth insulating layer 132. For example, a portion of the first connection electrode BE1 (for example, one end of the first connection electrode BE1 located on the eighth insulating layer 132) may be directly located on the first side portion of the light emitting element LE including the first contact electrode CTE1. Accordingly, the first connection electrode BE1 may be electrically connected to the first contact electrode CTE1 of the light emitting element LE. The first connection electrode BE1 may have a shape and/or an inclination corresponding to the first side portion of the light emitting element LE on the first side portion of the light emitting element LE.

In one or more embodiments, the first connection electrode BE1 may be in contact with the first reflective electrode RFL1 on the pixel electrode PXE. For example, another portion of the first connection electrode BE1 (for example, the other end of the first connection electrode BE1 located on a portion of the pixel electrode PXE that is not covered with the eighth insulating layer 132) may be directly located on a portion of the first reflective electrode RFL1 that is not covered with the eighth insulating layer 132. Accordingly, the first connection electrode BE1 may be electrically connected to the first reflective electrode RFL1, and may be electrically connected to the pixel electrode PXE through the first reflective electrode RFL1. In some embodiments, when the sub-pixel SPX does not include the first reflective electrode RFL1 or when the pixel electrode PXE and the first reflective electrode RFL1 are integrated, the first connection electrode BE1 may be electrically connected to the pixel electrode PXE by being in contact with the pixel electrode PXE on a portion of the pixel electrode PXE that is not covered with the eighth insulating layer 132.

The second connection electrode BE2 connects the second contact electrode CTE2 of the light emitting element LE to the common electrode CE. For example, the second connection electrode BE2 of the first sub-pixel SPX1 may electrically connect the second contact electrode CTE2 of the first light emitting element LE1 and the common electrode CE. The second connection electrode BE2 of the second sub-pixel SPX2 may electrically connect the second contact electrode CTE2 of the second light emitting element LE2 and the common electrode CE. The third connection electrode BE3 of the third sub-pixel SPX3 may electrically connect the second contact electrode CTE2 of the third light emitting element LE3 and the common electrode CE.

In one or more embodiments, the second connection electrode BE2 may be in contact with the second contact electrode CTE2 of the light emitting element LE on the eighth insulating layer 132. For example, a portion of the second connection electrode BE2 (for example, one end of the second connection electrode BE2 located on the eighth insulating layer 132) may be directly located on the second side portion of the light emitting element LE including the second contact electrode CTE2. Accordingly, the second connection electrode BE2 may be electrically connected to the second contact electrode CTE2 of the light emitting element LE. The second connection electrode BE2 may have a shape and/or an inclination corresponding to the second side portion of the light emitting element LE on the second side portion of the light emitting element LE.

In one or more embodiments, the second connection electrode BE2 may be in contact with the second reflective electrode RFL2 on the common electrode CE. For example, another portion of the second connection electrode BE2 (for example, the other end of the second connection electrode BE2 located on a portion of the common electrode CE that is not covered with the eighth insulating layer 132) may be directly located on a portion of the second reflective electrode RFL2 that is not covered with the eighth insulating layer 132. Accordingly, the second connection electrode BE2 may be electrically connected to the second reflective electrode RFL2, and may be electrically connected to the common electrode CE through the second reflective electrode RFL2. In some embodiments, when the sub-pixel SPX does not include the second reflective electrode RFL2 or when the common electrode CE and the second reflective electrode RFL2 are integrated, the second connection electrode BE2 may be electrically connected to the common electrode CE by being in contact with the common electrode CE on a portion of the common electrode CE that is not covered with the eighth insulating layer 132.

Each of the first connection electrode BE1 and the second connection electrode BE2 may include at least one conductive material, for example, a transparent conductive material such as indium tin oxide (ITO) and/or indium zinc oxide (IZO) (for example, a transparent conductive oxide (TCO)). In some embodiments, each of the first connection electrode BE1 and the second connection electrode BE2 may include any one selected from among molybdenum (Mo), aluminum (Al), chromium (Cr), gold (Au), titanium (Ti), nickel (Ni), neodymium (Nd) and copper (Cu).

The conductive layer E1 of the light emitting element LE may be in contact with and/or connected to the first contact electrode CTE1, and may be electrically connected to the first connection electrode BE1 through the first contact electrode CTE1. The second semiconductor layer SEM2 of the light emitting element LE may be in contact with and/or connected to the second contact electrode CTE2 formed in the hole LEH, and may be electrically connected to the second connection electrode BE2 through the second contact electrode CTE2.

The light transmitting patterns OC may be arranged on the connection electrodes BE. By way of example, the first pattern OC1 (for example, the first light transmitting pattern or first barrier) may be arranged on the first connection electrode BE1, and the second pattern OC2 (for example, the second light transmitting pattern or second barrier) may be arranged on the second connection electrode BE2. The first pattern OC1 may have a planar shape corresponding to the first connection electrode BE1, and may cover the first connection electrode BE1. The second pattern OC2 may have a planar shape corresponding to the second connection electrode BE2, and may cover the second connection electrode BE2.

The first pattern OC1 and the second pattern OC2 may surround different portions of the light emitting element LE and may be spaced apart from each other while the light emitting element LE is interposed between the first pattern OC1 and the second pattern OC2. By way of example, as illustrated in FIGS. 6 and 7, the first pattern OC1 may surround the first side portion of the light emitting element LE (for example, the side portion of the light emitting element LE located on the pixel electrode PXE), and the second pattern OC2 may surround the second side portion of the light emitting element LE (for example, the side portion of the light emitting element LE located on the common electrode CE. In one or more embodiments, the first pattern OC1 and the second pattern OC2 may not be located on the remaining side portion of the light emitting element LE, for example, the third side portion of the light emitting element LE including a side portion that does not overlap the pixel electrode PXE and the common electrode CE, and may be spaced apart from each other while the third side portion of the light emitting element LE is interposed between the first pattern OC1 and the second pattern OC2.

In one or more embodiments, the light transmitting patterns OC may include side surfaces having a reverse tapered shape. For example, each of the first pattern OC1 and the second pattern OC2 may include a side surface having a reverse tapered shape at a portion located opposite to the light emitting element LE. For example, each of the first pattern OC1 and the second pattern OC2 may have a shape with its width gradually increasing upwards at an outer portion of the emission area EA (for example, the boundary between the emission area EA) and the non-emission area NEA).

In one or more embodiments, the light transmitting patterns OC may include a negative type or kind photoresist material, and may include side surfaces having a reverse tapered shape. In one or more embodiments, the light transmitting patterns OC may include a light-transmissive organic material, and may include a gently contoured surface (e.g., including smooth curved lines and/or angles rather than straight lines and sharp angles). By way of example, among negative type or kind photoresist materials, a light-transmissive organic material through which the light emitted from the light emitting element LE can be transmitted may be used to form the first pattern OC1 and the second pattern OC2. Accordingly, each of the first pattern OC1 and the second pattern OC2 may be formed as a pattern in a gentle shape (e.g., including smooth curved lines and/or angles) having an overall reverse tapered shape, and may be formed as a light transmitting pattern through which the light emitted from the light emitting element LE can be transmitted. In one or more embodiments, the light transmitting patterns OC may include a light-transmissive organic material such as an epoxy resin, an acrylic resin, and/or an imide resin, but the present disclosure is not limited thereto.

In one or more embodiments, the range of the angle at which the side surfaces of the light transmitting patterns OC are tilted may be appropriately or suitably adjusted or changed by adjusting the process conditions, and/or the like, applied to the formation of the light transmitting patterns OC. For example, the first pattern OC1 and the second pattern OC2 may be formed such that the side surface of each of the first pattern OC1 and the second pattern OC2, which are arranged at the outer portion of the emission area EA, has an angle of approximately and/or overall in the range of 100° to 120° with respect to the pixel electrode PXE and the common electrode CE.

The side surfaces of the light transmitting patterns OC that are respectively in contact with the connection electrodes BE may have a shape and/or an inclination corresponding to the connection electrodes BE. For example, the inner surface of the first pattern OC1 in contact with the first connection electrode BE1 on the first side portion of the light emitting element LE may have a shape and/or an inclination corresponding to the shape and/or the inclination of the first side portion of the light emitting element LE and the first connection electrode BE1. In one or more embodiments, the inner surface of the second pattern OC2 in contact with the second connection electrode BE2 on the second side portion of the light emitting element LE may have a shape and/or an inclination corresponding to the shape and/or the inclination of the second side portion of the light emitting element LE and the second connection electrode BE2.

In one or more embodiments, the light transmitting patterns OC may be formed to have a thickness and height suitable for eliminating, alleviating, or reducing a stepped portion caused by the light emitting elements LE. For example, the light transmitting patterns OC may be formed at a height similar to that of the light emitting elements LE, and may surround the side surfaces of the light emitting elements LE. The light transmitting patterns OC may mitigate (e.g., even out) the stepped portion caused by the light emitting elements LE.

In one or more embodiments, the light transmitting patterns OC may be used as a mask for forming the connection electrodes BE, and may thus be formed in a shape corresponding to the shape of the connection electrodes BE. For example, the light transmitting patterns OC and the connection electrodes BE may have substantially the same or similar shapes in plan view, and may have substantially the same or similar areas.

In one or more embodiments, when the light transmitting patterns OC are used as a mask to form the connection electrodes BE, the portions of the conductive film for forming the connection electrodes BE that are covered with the light transmitting patterns OC may remain and become the respective connection electrodes BE. In this case, the connection electrodes BE may be arranged at a height less than or equal to the height of the light transmitting patterns OC, and the top surfaces of the connection electrodes BE may be covered overall (e.g., entirely covered) with the light transmitting patterns OC. For example, the first pattern OC1 may be formed at a height greater than or equal to the height of the first connection electrode BE1 to cover the first connection electrode BE1, and the second pattern OC2 may be formed at a height greater than or equal to the height of the second connection electrode BE2 to cover the second connection electrode BE2. In one or more embodiments, one end of each of the first connection electrode BE1 and the second connection electrode BE2 in contact with the top surface of the light emitting element LE may not be covered with the first pattern OC1 and the second pattern OC2.

The ninth insulating layer 134 may be located on the light emitting elements LE and the light transmitting patterns OC. By way of example, the ninth insulating layer 134 may cover the pixel electrodes PXE, the common electrode CE, the reflective electrodes RFL, the light emitting elements LE, and the light transmitting patterns OC as a whole.

The ninth insulating layer 134 may include at least one insulating material. By way of example, the ninth insulating layer 134 may include an inorganic insulating material (for example, silicon oxynitride (SiON) and/or the like) suitable for protecting the pixel electrodes PXE, the common electrode CE, the reflective electrodes RFL, the light emitting elements LE, and the light transmitting patterns OC.

The reflective films RF may be arranged on the ninth insulating layer 134. The reflective films RF may be arranged on the side surfaces of the light transmitting patterns OC. For example, the first reflective film RF1 may be placed on the side surface of the first pattern OC1 located at the outer portion of the emission area EA and a portion of the ninth insulating layer 134 covering the side surface of the first pattern OC1, and the second reflective film RF2 may be placed on the side surface of the second pattern OC2 located at the outer portion of the emission area EA and a portion of the ninth insulating layer 134 covering the side surface of the second pattern OC2. The first reflective film RF1 and the second reflective film RF2 may face each other while the light emitting element LE, the first connection electrode BE1, the second connection electrode BE2, the first pattern OC1, and the second pattern OC2 are interposed between the first reflective film RF1 and the second reflective film RF2.

The reflective films RF may include a material having suitably high reflectivity for the light emitted from the light emitting element LE. For example, the reflective films RF may include aluminum (Al) and/or other metals having suitably high light reflectivity. However, the embodiments are not limited thereto. For example, in some embodiments, the reflective films RF may be formed as a distributed Bragg reflector including inorganic films (for example, silicon nitride (SiNx, e.g., Si₃N₄), silicon oxide (SiOx, e.g., SiO₂), silicon oxynitride (SiOxNy, e.g., SiON), titanium oxide (TiOx, e.g., TiO₂), and/or aluminum oxide (AlOx, e.g., Al₂O₃)) having different refractive indices and arranged alternately.

The reflective films RF may reflect, from the light emitted from the light emitting element LE, the light that has passed through the light transmissive patterns OC and propagates in the lateral direction (for example, lateral light). Accordingly, the amount of the light emitted in the upward direction from each sub-pixel SPX may be increased, so that the light efficiency of the sub-pixels SPX may be improved.

The reflective films RF may have a shape and/or an inclination corresponding to the lateral shape of the light transmitting patterns OC. For example, the first reflective film RF1 may have a shape and/or an inclination corresponding to the lateral shape of the first pattern OC1, and may surround the first side portion of the light emitting element LE. The second reflective film RF2 may have a shape and/or an inclination corresponding to the lateral shape of the second pattern OC2, and may surround the second side portion of the light emitting element LE.

In one or more embodiments, the first pattern OC1 may include a side surface in a reverse tapered shape having an angle of about 100° to 120° with respect to the pixel electrode PXE, and the first reflective film RF1 may be inclined at an angle θ1 of about 100° to 120° with respect to the pixel electrode PXE. For example, the first reflective film RF1 may become farther from the central portion of the emission area EA as it goes from its lower portion adjacent to the backplane layer 120 to its upper portion adjacent to the optical layer 140. In one or more embodiments, the angle formed by at least a part of the first reflective film RF1 and the pixel electrode PXE may be in the range of 100° to 120°. The second pattern OC2 may include a side surface in a reverse tapered shape having an angle of about 100° to 120° with respect to the common electrode CE, and the second reflective film RF2 may be inclined at an angle θ2 of about 100° to 120° with respect to the common electrode CE. For example, the second reflective film RF2 may become farther from the central portion of the emission area EA as it goes from its lower portion adjacent to the backplane layer 120 to its upper portion adjacent to the optical layer 140. In one or more embodiments, the angle formed by at least a part of the second reflective film RF2 and the common electrode CE may be in the range of 100° to 120°.

In the present embodiments, when the first reflective film RF1 and the second reflective film RF2 are tilted at the angles θ1 and θ2 of about 100° to 120° with respect to the pixel electrode PXE and the common electrode CE, respectively, the light reflectivity by the reflective films RF may be effectively or suitably improved (for example, increased, improved, or optimized). In contrast, when the angles formed by the reflective films RF with respect to the pixel electrode PXE and the common electrode CE, respectively, are less than 100°, the light efficiency improvement aspect of the sub-pixel SPX due to the light reflected by the reflective films RF is reduced, making it difficult to obtain a significant or suitable effect. In addition, when the angles formed by the reflective films RF with respect to the pixel electrode PXE and the common electrode CE, respectively, are greater than 120°, the process of forming the first pattern OC1 and the second pattern OC2 in a corresponding shape may become difficult, and the width of the top surfaces of the first pattern OC1 and the second pattern OC2 may increase, resulting in an increase in the distance between the upper ends of the first reflective film RF1 and the second reflective film RF2 and the light emitting element LE, so that the light efficiency improvement aspect of the sub-pixel SPX by the reflective films RF may be decreased.

In one or more embodiments, the angle θ1 formed by the first reflective film RF1 and the pixel electrode PXE may be equal to the angle θ2 formed by the second reflective film RF2 and the common electrode CE, but the present disclosure is not limited thereto. In one or more embodiments, the angle θ1 formed by the first reflective film RF1 and the pixel electrode PXE and the angle θ2 formed by the second reflective film RF2 and the common electrode CE may be approximately 110°, so that the light efficiency improvement aspect by the first reflective film RF1 and the second reflective film RF2 may be maximized or increased. However, the embodiments are not limited thereto. For example, the angle range capable of maximizing or increasing the light efficiency improvement aspect by the first reflective film RF1 and the second reflective film RF2 in each display panel 100 may be derived (or suitably adjusted), and the light transmitting patterns OC and the reflective films RF may be formed in corresponding shapes.

The light blocking layer BM may be located on the ninth insulating layer 134 and the reflective films RF. The light blocking layer BM may be located in the non-emission area NEA, and may surround the emission area EA in which the light emitting element LE is located. For example, the light blocking layer BM may be located at least on the side surfaces of the first pattern OC1 and the first reflective film RF1 and the side surfaces of the second pattern OC2 and the second reflective film RF2. Accordingly, the light blocking layer BM may surround at least a part of the light emitting element LE including the first side portion and the second side portion.

The light blocking layer BM may include a light blocking material such as an inorganic black pigment such as carbon black and/or an organic black pigment. The light blocking layer BM may include an organic film such as acrylic resin, epoxy resin, phenolic resin, polyamide resin, polyimide resin and/or the like, but the present disclosure is not limited thereto. In one or more embodiments, the display panel 100 may further include a capping layer (e.g., an inorganic film) located on the light blocking layer BM.

The first overcoat layer 136 may be formed on the ninth insulating layer 134 and the light blocking layer BM. The first overcoat layer 136 may include a light-transmissive organic material (e.g., acrylic resin, epoxy resin, phenolic resin, polyamide resin, and/or polyimide resin), but the present disclosure is not limited thereto. The top surface of the first overcoat layer 136 may be substantially flat.

The optical layer 140 may be located on the first overcoat layer 136. The optical layer 140 may include color filters (for example, first, second, and third color filters CF1, CF2, and CF3) corresponding to the emission colors of the respective sub-pixels SPX, and a second overcoat layer 142 covering the color filters.

In one or more embodiments, the light emitting element LE may be to emit light of a color corresponding to the emission color of each sub-pixel SPX, and a color filter that selectively transmits the light of the color corresponding to the emission color of the light emitting element LE may be located on the light emitting element LE. For example, the first color filter CF1 that selectively transmits light of a first color emitted from the first light emitting element LE1 of the first sub-pixel SPX1 may be located on the first light emitting element LE1.

In some embodiments, the light emitting element LE of at least one sub-pixel SPX may be to emit light of a color different from the emission color of the corresponding sub-pixel SPX, and a light conversion layer (for example, a wavelength conversion layer) including wavelength conversion particles may be located on the light emitting element LE of the at least one sub-pixel SPX. For example, the optical layer 140 may further include a light conversion layer that is located between the color filter and the light emitting element LE of at least one sub-pixel SPX to convert the light emitted from the light emitting element LE into light corresponding to the emission color of the corresponding sub-pixel SPX.

FIG. 7 illustrates an example where the optical layer 140 includes color filters but does not include a light conversion layer.

For example, the color filters of the sub-pixels SPX may be arranged on the first overcoat layer 136. For example, the first color filter CF1 for selectively transmitting light of the first color may be located in the emission area EA of the first sub-pixel SPX1. The second color filter CF2 that selectively transmits light of a second color may be located in the emission area EA of the second sub-pixel SPX2, and the third color filter CF3 that selectively transmits light of a third color may be located in the emission area EA of the third sub-pixel SPX3.

In one or more embodiments, the color filters of the sub-pixels SPX may be located to overlap each other in the non-emission area NEA, thereby forming a light blocking pattern. For example, the first color filter CF1, the second color filter CF2, and the third color filter CF3 which are respectively arranged in the emission areas EA of the first sub-pixel SPX1, the second sub-pixel SPX2, and the third sub-pixel SPX3 may overlap each other in the non-emission area NEA. The second color filter CF2 may selectively transmit the light of the second color corresponding to the emission color of the second sub-pixel SPX2, and the third color filter CF3 may selectively transmit the light of the third color corresponding to the emission color of the third sub-pixel SPX3.

The second overcoat layer 142 may be located on the first color filter CF1, the second color filter CF2, and the third color filter CF3. In one or more embodiments, the second overcoat layer 142 may include a light-transmissive organic material, but the present disclosure is not limited thereto. The top surface of the second overcoat layer 142 may be substantially flat.

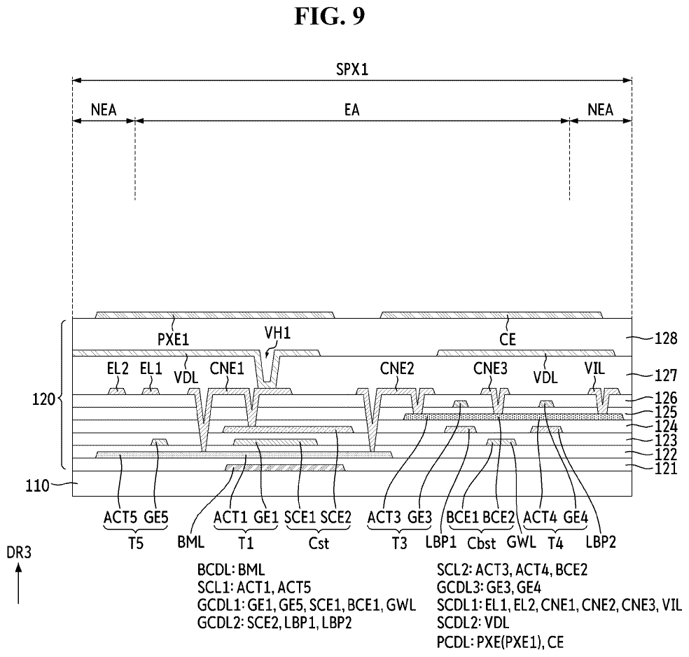

FIGS. 9 to 19 are cross-sectional views showing a method for manufacturing the display device according to one or more embodiments. For example, FIGS. 9 to 19 sequentially show manufacturing steps for forming the light emitting element layer 130 among manufacturing steps for manufacturing the display panel 100 according to the embodiment of FIG. 7.

Referring to FIG. 9 in addition to FIGS. 1 to 8, the pixel electrode layer PCDL may be formed on the substrate 110. For example, the backplane layer 120 may be formed on the substrate 110, and the pixel electrode PXE and the common electrode CE of each of the sub-pixels SPX may be formed on the backplane layer 120.

The patterns of the pixel electrode layer PCDL may be formed as single-layer or multi-layer patterns using at least one conductive material. For example, after forming a single-layer or multi-layer conductive film on the backplane layer 120 (for example, on the entire surface thereof) by using at least one conductive material suitable for forming the pixel electrodes PXE and the common electrode CE, a patterning process including an etching process for the conductive film may be performed to form the conductive film into patterns of the pixel electrode layer PCDL.

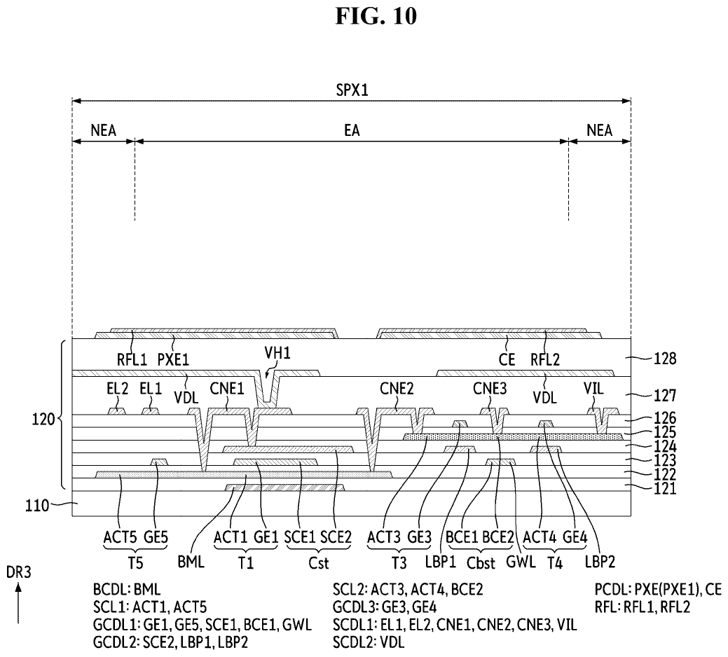

Referring to FIG. 10, the reflective electrodes RFL may be formed on the pixel electrode layer PCDL. For example, the first reflective electrode RFL1 may be formed on a portion of each of the pixel electrodes PXE, and the second reflective electrode RFL2 may be formed on a portion of the common electrode CE. In one or more embodiments, the reflective electrodes RFL may be formed using a conductive material such as metal. For example, a conductive film forming process and patterning process using at least one conductive material containing metal having suitably high reflectivity may be performed to form the reflective electrodes RFL on the pixel electrode layer PCDL.

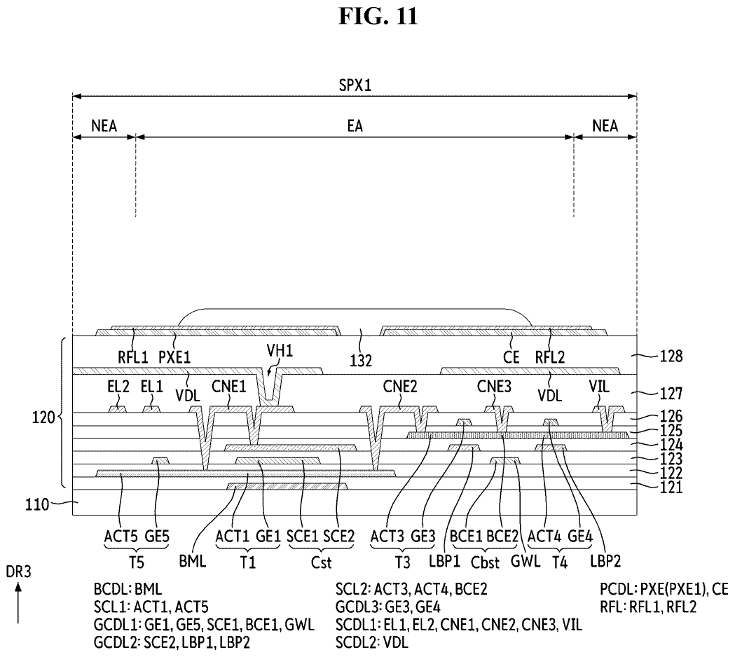

Referring to FIG. 11, the eighth insulating layer 132 (for example, an adhesive layer or a bonding layer) may be formed on the pixel electrode layer PCDL and the reflective electrodes RFL. For example, by using an organic insulating material having adhesiveness, the eighth insulating layer 132 may be formed in a portion of the emission area EA including a light emitting element area where each light emitting element LE is to be placed. The eighth insulating layer 132 may cover a portion of each pixel electrode PXE and a portion of the common electrode CE. When the display panel 100 includes the first reflective electrode RFL1 and the second reflective electrode RFL2 positioned below the light emitting element LE, the eighth insulating layer 132 may cover a portion of the first reflective electrode RFL1 and a portion of the second reflective electrode RFL2.

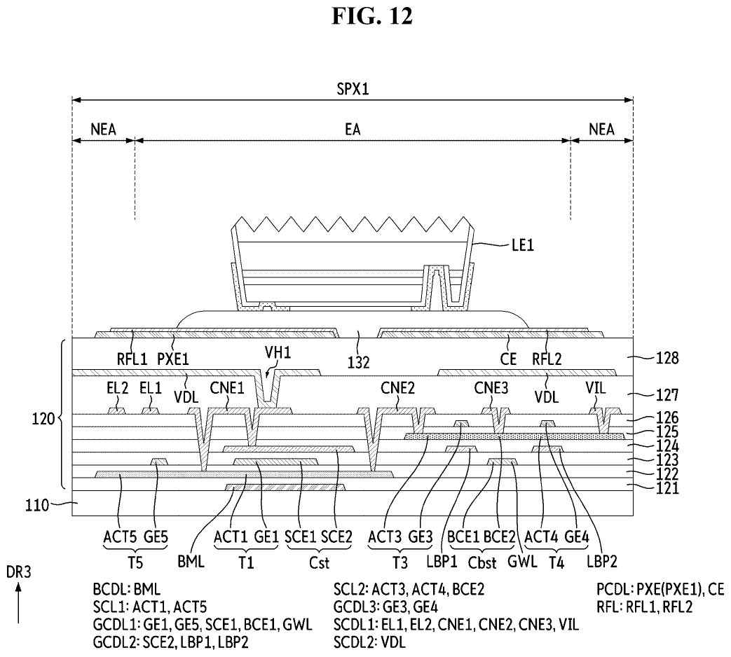

Referring to FIG. 12, the light emitting element LE of each sub-pixel SPX may be arranged on the eighth insulating layer 132. In one or more embodiments, the light emitting elements LE may be grown and formed on a semiconductor substrate such as a silicon substrate and/or a sapphire substrate and then transferred onto the pixel electrodes PXE and the common electrode CE of the display panel 100. Each light emitting element LE may be located in each light emitting element area LEA, and may be supported by the eighth insulating layer 132. In one or more embodiments, each light emitting element LE may be a flip-chip type or kind light emitting element including the semiconductor stack STC as well as the first and second contact electrodes CTE1 and CTE2 located on the side surfaces of the semiconductor stack STC, as illustrated in FIG. 8.

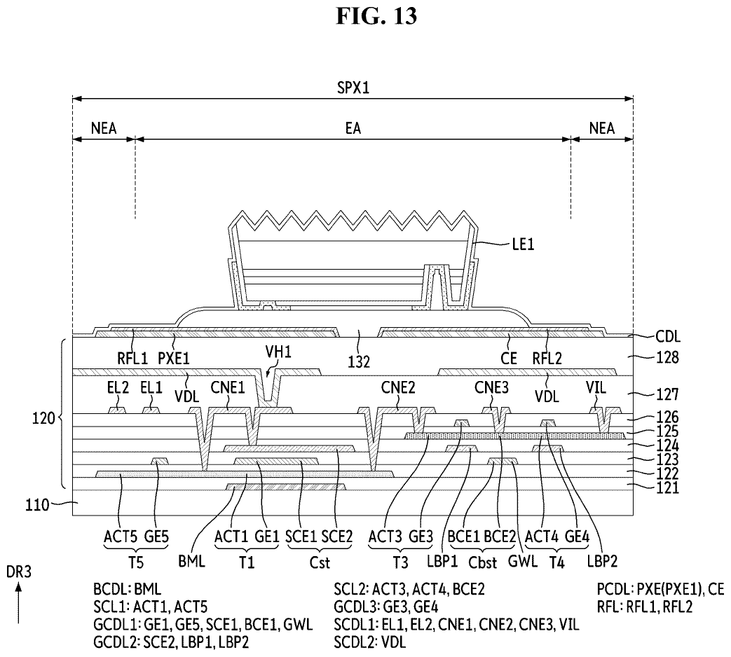

Referring to FIG. 13, a conductive film CDL may be formed on the pixel electrodes PXE, the common electrode CE, the reflective electrodes RFL, the eighth insulating layer 132, and the light emitting elements LE. The conductive film CDL is intended for forming the connection electrodes BE, and may be formed using at least one conductive material exemplified above as the material of the connection electrodes BE. For example, the conductive film CDL may be formed by depositing a transparent conductive oxide such as indium zinc oxide (IZO) and/or another suitable conductive material on the entire surface of the display area DA in which the light emitting elements LE are arranged. In one or more embodiments, the conductive film CDL may be formed by a sputtering method, but the material or the method for forming the conductive film CDL is not limited thereto.

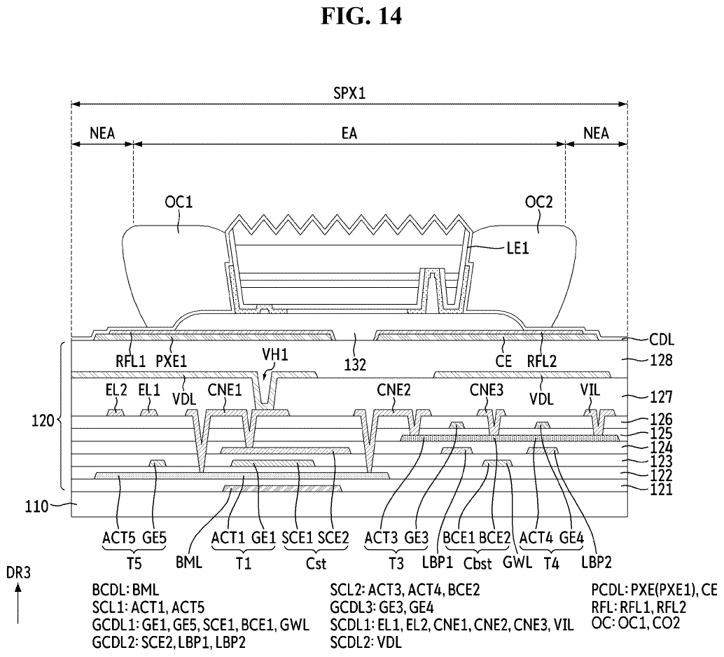

Referring to FIG. 14, the light transmitting patterns OC including the first pattern OC1 and the second pattern OC2 may be formed on the conductive film CDL. The first pattern OC1 may be formed to surround the first side portion of the light emitting element LE including the first contact electrode CTE1. For example, the first pattern OC1 may be formed on the periphery of the first side portion of the light emitting element LE and a portion of the first reflective electrode RFL1 (or pixel electrode PXE) that is not covered with the eighth insulating layer 132. The second pattern OC2 may be formed to surround the second side portion of the light emitting element LE including the second contact electrode CTE2. For example, the second pattern OC2 may be formed on the periphery of the second side portion of the light emitting element LE and a portion of the second reflective electrode RFL2 (or common electrode CE) that is not covered with the eighth insulating layer 132. The light transmitting patterns OC may be formed to have a thickness and a height suitable for alleviating or reducing the stepped portion caused by the light emitting elements LE of the respective sub-pixels SPX.

In one or more embodiments, the first pattern OC1 and the second pattern OC2 may be formed by a photolithography process using a negative type or kind photoresist material (for example, a light-transmissive organic material among negative type or kind photoresist materials). Accordingly, each of the first pattern OC1 and the second pattern OC2 may be formed to have a side surface of a reverse tapered shape.

By forming the light transmitting patterns OC using a negative type or kind photoresist material, each of the light transmitting patterns OC may be appropriately or suitably formed at a target position, and the photoresist material may be stably or suitably removed from other areas. For example, after the photoresist material is applied to the entire surface of the conductive film CDL to form a photoresist film, light may be irradiated to the photoresist film only at positions where the first connection electrode BE1 and the second connection electrode BE2 are to be formed. As a result, the first pattern OC1 and the second pattern OC2 may be formed at positions where the first connection electrode BE1 and the second connection electrode BE2 are to be formed respectively.

When forming the light transmitting patterns OC using the negative type or kind photoresist material, light may not be irradiated to the photoresist film at a position where the connection electrodes BE are not to be formed, including the periphery of the third side portion of the light emitting element LE. Accordingly, the photoresist film covering the third side portion of the light emitting element LE, and/or the like may be appropriately or suitably removed in a developing process, thereby preventing or reducing residues of the photoresist film from remaining on the third side portion of the light emitting element LE.

In one or more embodiments, the shapes of the first pattern OC1 and the second pattern OC2 may be controlled or selected by controlling the process of forming the first pattern OC1 and the second pattern OC2. By way of example, the shapes of the side surfaces of the first pattern OC1 and the second pattern OC2 may be controlled or selected by controlling the conditions for performing the photolithography process for forming the first pattern OC1 and the second pattern OC2. In one or more embodiments, the first pattern OC1 and the second pattern OC2 may be formed in a shape that includes a side surface tilted at an angle of approximately and/or overall in the range of 100° to 120° with respect to the pixel electrode PXE and the common electrode CE, respectively.

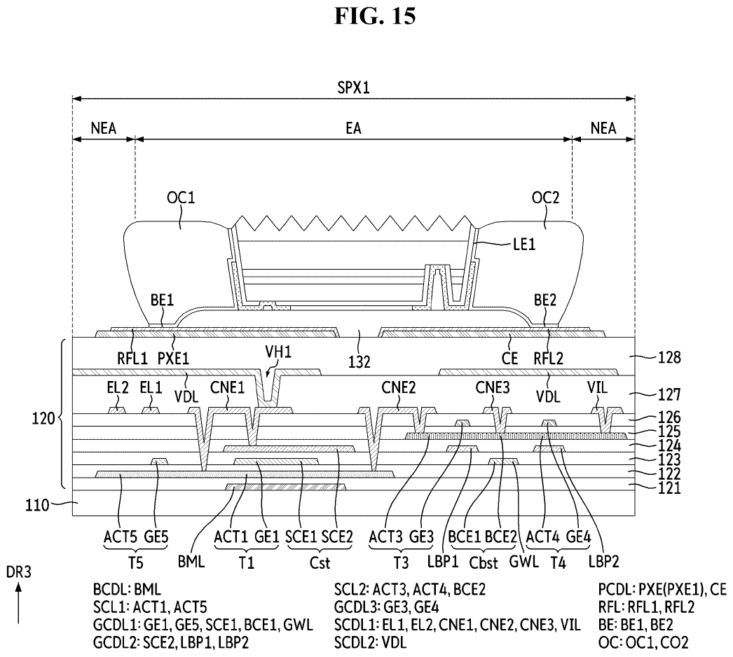

Referring to FIG. 15, the connection electrodes BE may be formed under the light transmitting patterns OC. For example, by etching the conductive film CDL using the light transmitting patterns OC as a mask, the connection electrodes BE having shapes and sizes corresponding to the shapes of the corresponding light transmitting patterns OC may be formed under the respective light transmitting patterns OC. For example, the conductive film CDL may be patterned into the first connection electrode BE1 and the second connection electrode BE2 by performing a wet etching process using the first pattern OC1 and the second pattern OC2 arranged in each emission area EA as a mask. As a result, the first connection electrode BE1 may be formed under the first pattern OC1, and the second connection electrode BE2 may be formed under the second pattern OC2.

Accordingly, the first connection electrode BE1 may be formed to surround the first side portion of the light emitting element LE including the first contact electrode CTE1. For example, the first connection electrode BE1 may be formed on the periphery of the first side portion of the light emitting element LE and a portion of the first reflective electrode RFL1 (or pixel electrode PXE) that is not covered with the eighth insulating layer 132. The first connection electrode BE1 may connect the first contact electrode CTE1 of the light emitting element LE and the pixel electrode PXE. For example, the first connection electrode BE1 may be electrically connected between the first reflective electrode RFL1 connected to the pixel electrode PXE and the first contact electrode CTE1 of the light emitting element LE.

The second connection electrode BE2 may be formed to surround the second side portion of the light emitting element LE including the second contact electrode CTE2. For example, the second connection electrode BE2 may be formed on the periphery of the second side portion of the light emitting element LE and a portion of the second reflective electrode RFL2 (or common electrode CE) that is not covered with the eighth insulating layer 132. The second connection electrode BE2 may connect the second contact electrode CTE2 of the light emitting element LE and the common electrode CE. By way of example, the second connection electrode BE2 may be electrically connected between the second reflective electrode RFL2 connected to the common electrode CE and the second contact electrode CTE2 of the light emitting element LE.

In the process of forming the light transmitting patterns OC described above, because the light transmitting patterns OC are formed using the negative type or kind photoresist material, no residue of the photoresist film may remain on the third side portion of the light emitting element LE. Accordingly, as the conductive film CDL is appropriately or suitably removed from the portion covering the third side portion of the light emitting element LE, and/or the like, the first connection electrode BE1 and the second connection electrode BE2 may be stably separated. Therefore, electrical stability (for example, insulation) between the first connection electrode BE1 and the second connection electrode BE2 may be secured or improved.

In contrast, when forming the light transmitting patterns OC using a positive type or kind photoresist material and forming the connection electrodes BE using those light transmitting patterns OC as a mask, or when forming the connection electrodes BE using an additional mask pattern made of a positive type or kind photoresist material, there is a risk that a short circuit defect may occur between the first connection electrode BE1 and the second connection electrode BE2. For example, when etching the conductive film CDL using patterns including a positive type or kind photoresist material as a mask, a residue of the photoresist film may remain on the third side portion of the light emitting element LE. Accordingly, there is a risk of a short circuit defect occurring as a result of the first connection electrode BE1 and the second connection electrode BE2 not being properly separated.

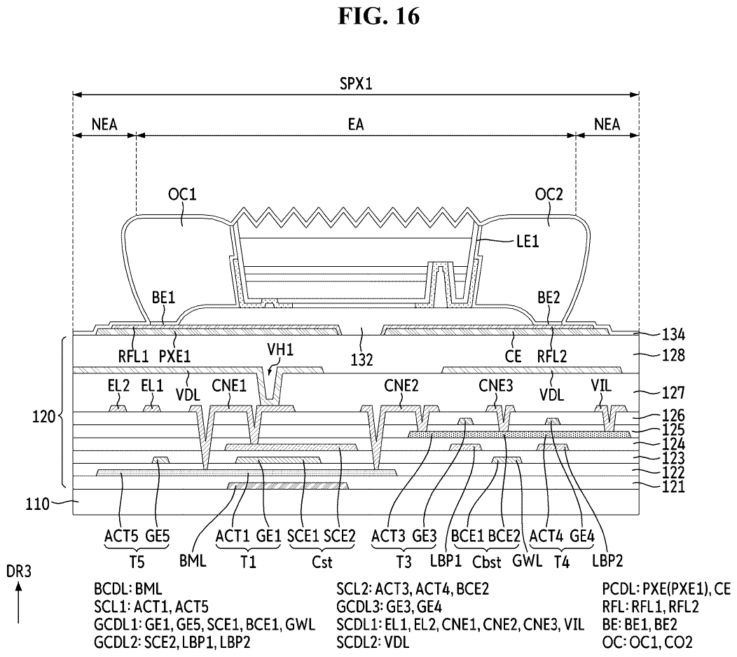

Referring to FIG. 16, the ninth insulating layer 134 may be formed on the light emitting elements LE and the light transmitting patterns OC. For example, the ninth insulating layer 134 may be formed on the entire surfaces of the pixel electrodes PXE, the common electrode CE, the reflective electrodes RFL, the light emitting elements LE, and the light transmitting patterns OC.

The ninth insulating layer 134 may be formed of a material and with a thickness suitable for protecting the electrodes, the patterns, and/or the light emitting elements LE arranged in the light emitting element layer 130. In one or more embodiments, the ninth insulating layer 134 may be formed as a thin film using at least one inorganic insulating material (for example, silicon oxynitride (SiON) and/or the like).

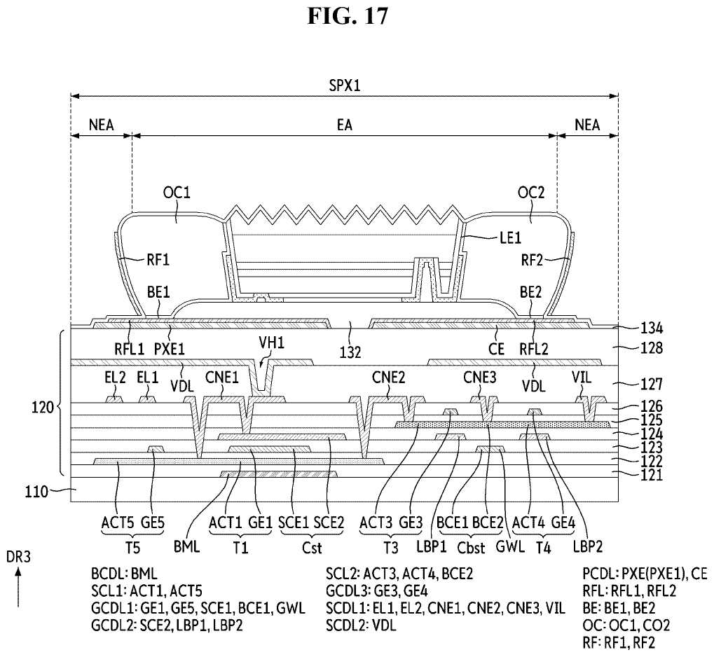

Referring to FIG. 17, the reflective films RF may be formed on the side surfaces of the light transmitting patterns OC. By way of example, the first reflective film RF1 may be formed on a portion of the ninth insulating layer 134 covering the side surface of the first pattern OC1, and the second reflective film RF2 may be formed on another portion of the ninth insulating layer 134 covering the side surface of the second pattern OC2. The first reflective film RF1 and the second reflective film RF2 may be formed using the material exemplified above as the material of the reflective films RF.

The first reflective film RF1 and the second reflective film RF2 may have shapes and/or inclinations corresponding to the shapes of the side surfaces of the first pattern OC1 and the second pattern OC2, respectively. For example, the first reflective film RF1 may be inclined at the angle θ1 (see FIG. 7) of about 100° to 120° with respect to the pixel electrode PXE, and the second reflective film RF2 may be inclined at the angle θ2 (see FIG. 7) of about 100° to 120° with respect to the common electrode CE.

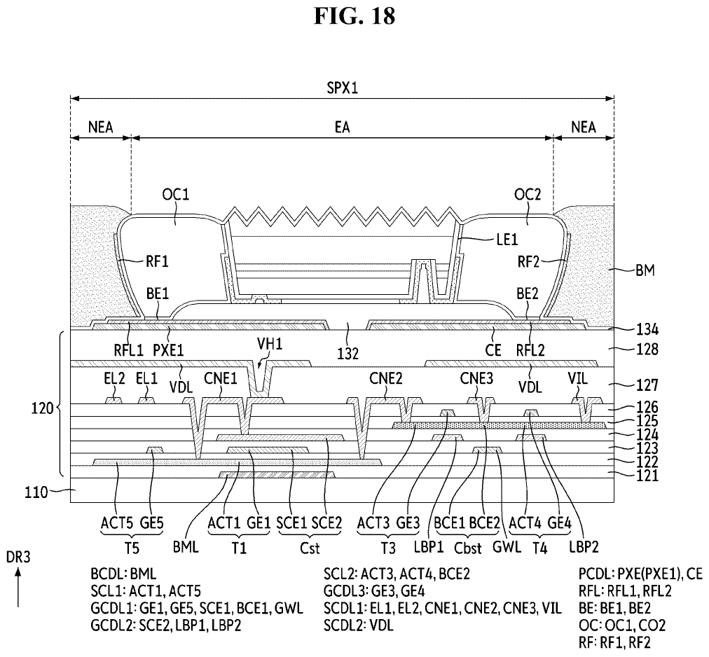

Referring to FIG. 18, the light blocking layer BM may be formed in the non-emission area NEA. For example, the light blocking layer BM may be formed on the side surfaces of the light transmitting patterns OC and the reflective films RF. The light blocking layer BM may surround at least a part of the light emitting element LE. For example, the light blocking layer BM may surround the first side portion and the second side portion of the light emitting element LE. In one or more embodiments, the light blocking layer BM may be located on opposite sides of the third side portion of the light emitting element LE, but the present disclosure is not limited thereto. The light blocking layer BM may be formed using the material exemplified above as the material of the light blocking layer BM.

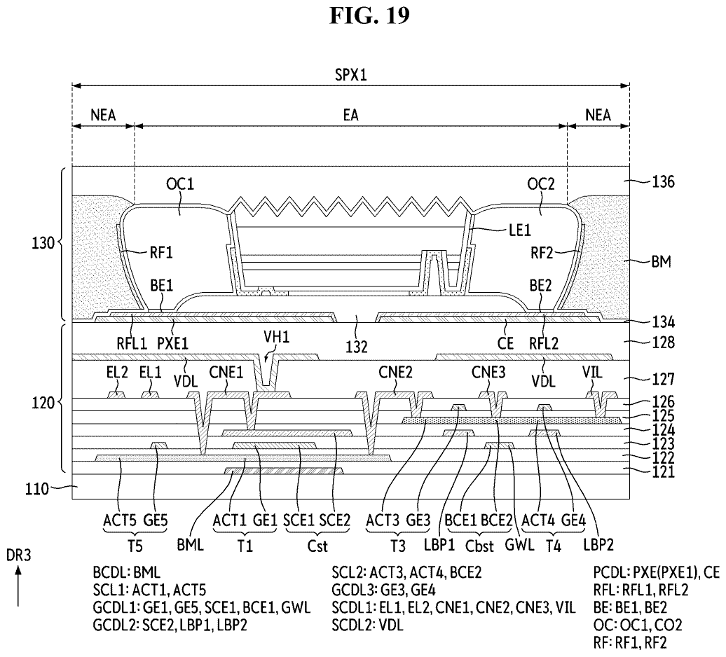

Referring to FIG. 19, the first overcoat layer 136 may be formed on the ninth insulating layer 134 and the light blocking layer BM. The first overcoat layer 136 may be formed using the light-transmissive material exemplified above (for example, a light-transmissive organic material), and the top surface of the first overcoat layer 136 may be substantially flat.

Through the aforementioned process with reference to FIGS. 9 to 19, the light emitting element layer 130 of the display panel 100 according to one or more embodiments may be formed. Thereafter, the optical layer 140 of FIG. 7 may be formed on the light emitting element layer 130. Accordingly, the display panel 100 according to the embodiment of FIG. 7 may be manufactured.

As described herein, the display device 1 according to the embodiments may include the first connection electrode BE1 connecting a portion (for example, the first contact electrode CTE1) of the light emitting element LE to the pixel electrode PXE, the second connection electrode BE2 connecting another portion (for example, the second contact electrode CTE2) of the light emitting element LE to the common electrode CE, the first pattern OC1 located on the first connection electrode BE1, and the second pattern OC2 located on the second connection electrode BE2 and spaced apart from the first pattern OC1. In some embodiments, the first connection electrode BE1 and the second connection electrode BE2 may be formed under the first pattern OC1 and the second pattern OC2, respectively, by utilizing the first pattern OC1 and the second pattern OC2 (e.g., as a mask). In accordance with the display device 1 and the manufacturing method thereof according to the embodiments, the first connection electrode BE1 and the second connection electrode BE2 may be stably or suitably separated to prevent or reduce a short circuit defect between the pixel electrode PXE and the common electrode CE, and the reliability of the display device 1 may be secured or improved.

In some embodiments, the first pattern OC1 and the second pattern OC2 may surround different side portions of the light emitting element LE, and may include side surfaces having a reverse tapered shape. In some embodiments, by forming the first pattern OC1 and the second pattern OC2 using a negative type or kind photoresist material, the first pattern OC1 and the second pattern OC2 may be appropriately or suitably and/or easily formed into desired or required shapes, and the first pattern OC1 and the second pattern OC2 may be stably or suitably separated.

In some embodiments, the display device 1 may further include the first reflective film RF1 located on the side surface of the first pattern OC1, and the second reflective film RF2 located on the side surface of the second pattern OC2. The first reflective film RF1 and the second reflective film RF2 may be inclined at shapes or angles corresponding to the side surfaces of the first pattern OC1 and the second pattern OC2 with respect to the pixel electrode PXE and the common electrode CE, respectively. For example, the first reflective film RF1 and the second reflective film RF2 may be inclined at an angle greater than 90°, for example, at an angle in the range of 100° to 120° with respect to the pixel electrode PXE and the common electrode CE, respectively. This allows the light traveling in the lateral direction toward the first reflective film RF1 and the second reflective film RF2 to be effectively or suitably reflected, so that the light emission rate of the sub-pixel SPX may be increased. In accordance with the display device 1 and the manufacturing method thereof according to the embodiments, the light efficiency of the display device 1 may be improved.

The display device 1 according to at least one of the above-described embodiments may be applied to one or more suitable electronic devices. The electronic device according to one or more embodiments may include the above-described display device 1 (or a display module including the display panel 100 according to at least one embodiment), and may further include modules and/or devices having other additional functions in addition to the display device 1.

For example, the electronic device may include the display panel 100 having the first pattern OC1 and the second pattern OC2 according to the embodiments. Accordingly, a short circuit defect between the pixel electrode PXE and the common electrode CE may be prevented or reduced, and the reliability of the electronic device may be secured or improved. In some embodiments, the electronic device may further include the first reflective film RF1 and the second reflective film RF2 according to the embodiments. Accordingly, light efficiency of the electronic device may be improved.

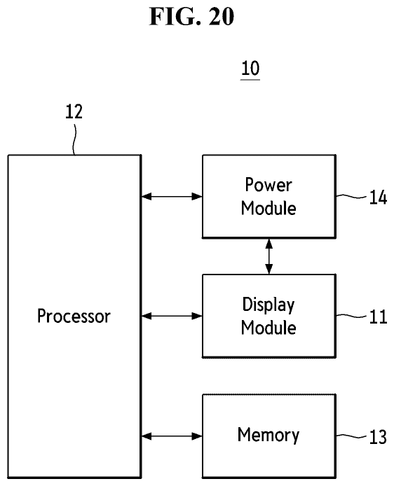

FIG. 20 is a block diagram of an electronic device according to one or more embodiments. Referring to FIG. 20, an electronic device 10 according to one or more embodiments may include a display module 11, a processor 12, a memory 13, and a power module 14.

The electronic device 10 may output various information in the form of images through the display module 11. For example, when the processor 12 executes an application stored in the memory 13, image information provided by the application may be provided to a user through the display module 11.

The display module 11 may include the display panel 100 for displaying an image. For example, the display module 11 may include the display panel 100 according to at least one of the aforementioned embodiments.

The processor 12 may include at least one selected from among a central processing unit (CPU), an application processor (AP), a graphic processing unit (GPU), a communication processor (CP), an image signal processor (ISP), and a controller.

The memory 15 may store data information desired or required for the operation of the processor 12 and/or the display module 11. For example, the memory 15 may store an image data signal and/or an input control signal.

The processor 12 may control the display module 11 using information stored in the memory 15. The processor 12 may be to transmit the image data signal and/or the input control signal stored in the memory 15 to the display module 11. For example, when the processor 12 executes an application stored in the memory 15, an image data signal and/or an input control signal is transmitted to the display module 11, and the display module 11 may process the received signal and output image information through a display screen.

The power module 14 may include a power supply module, such as a power adapter and/or a battery device, and a power conversion module that converts power supplied by the power supply module to generate power desired or required for the operation of the electronic device 10.

At least one of the components of the electronic device 10 described above may be included in the display device 1 according to the embodiments described above. Further, some of individual modules functionally included in one module may be included in the display device 1 and some others may be provided separately from the display device 1. For example, the display device 1 may include the display module 11, and the processor 12, the memory 13, and the power module 14 may be provided in the form of other devices in the electronic device 10 other than the display device 1.

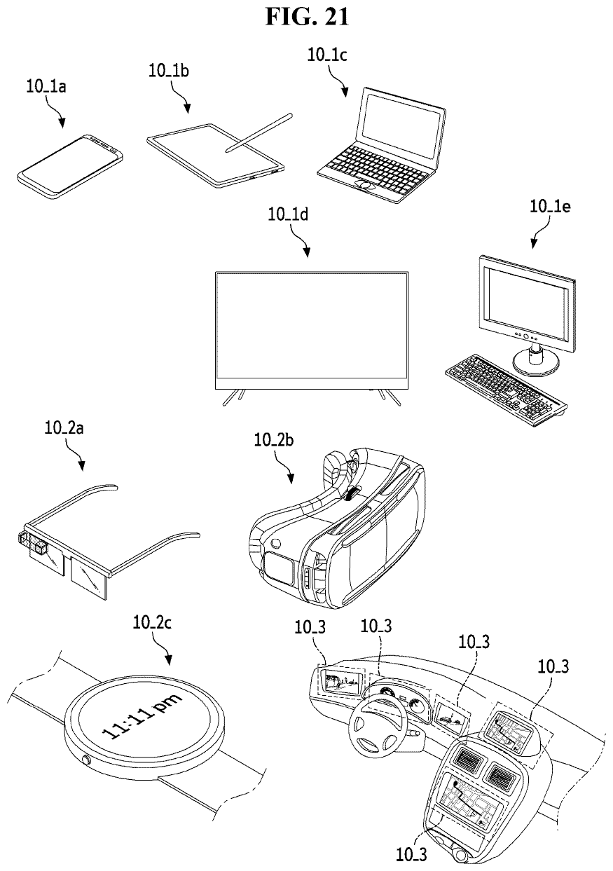

FIG. 21 includes schematic views of electronic devices according to one or more embodiments.

Referring to FIG. 21, one or more suitable electronic devices to which the display device 1 according to one or more embodiments is applied may include not only an image display electronic device (such as a smartphone 10_1a, a tablet PC 10_1b, a laptop 10_1c, a TV 10_1d, and/or a desk monitor 10_1e), but also a wearable electronic device including a display module (such as smart glasses 10_2a, a head mounted display 10_2b, and/or a smart watch 10_2c), and/or a vehicle electronic device 10_3 including a display module (such as a center fascia, a dashboard of an automobile, a center information display (CID) placed on the dashboard, a room mirror display, and/or the like).

In concluding the detailed description, those skilled in the art will appreciate that many variations and modifications can be made to the embodiments without substantially departing from the principles of the present disclosure. Therefore, the disclosed embodiments of the invention are used in a generic and descriptive sense only and not for purposes of limitation. It is therefore to be understood that various modifications to the disclosed embodiments, as well as other example embodiments, are intended to be included within the spirit and scope of the present disclosure as defined in the appended claims, and their equivalents.

What is claimed is:

1. A display device comprising:
a pixel electrode and a common electrode on a substrate;
an insulating layer on a portion of each of the pixel electrode and the common electrode;
a light emitting element on the insulating layer, the light emitting element comprising a semiconductor stack, and a first contact electrode and a second contact electrode on a side surface of the semiconductor stack;
a first connection electrode on the insulating layer and on a first side portion of a side surface of the light emitting element, which comprises the first contact electrode, the first connection electrode connecting the first contact electrode and the pixel electrode;
a second connection electrode on the insulating layer and on a second side portion of the side surface of the light emitting element, which comprises the second contact electrode, the second connection electrode connecting the second contact electrode and the common electrode;
a first pattern on the first connection electrode and surrounding the first side portion of the light emitting element; and
a second pattern on the second connection electrode, surrounding the second side portion of the light emitting element, and spaced apart from the first pattern.

2. The display device of claim 1, wherein the first pattern and the second pattern comprise a negative type photoresist material and comprise a side surface having a reverse tapered shape.

3. The display device of claim 2, further comprising:
a first reflective film on a side surface of the first pattern and surrounding the first side portion of the light emitting element; and
a second reflective film on a side surface of the second pattern and surrounding the second side portion of the light emitting element.

4. The display device of claim 3, wherein an angle formed by at least a part of the first reflective film and the pixel electrode is 100° to 120°, and
an angle formed by at least a part of the second reflective film and the common electrode is 100° to 120°.

5. The display device of claim 1, wherein the first pattern and the second pattern comprise a light-transmissive organic material through which light emitted from the light emitting element can be transmitted.

6. The display device of claim 1, wherein a height of the first pattern is greater than or equal to a height of the first connection electrode, and
a height of the second pattern is greater than or equal to a height of the second connection electrode.

7. The display device of claim 1, wherein the first pattern, when viewed in plan view, has a shape and size corresponding to the first connection electrode, and
the second pattern, when viewed in plan view, has a shape and size corresponding to the second connection electrode.

8. The display device of claim 1, wherein the side surface of the light emitting element further comprises a third side portion between the first side portion and the second side portion, and
the first connection electrode and the second connection electrode are spaced apart from each other with the third side portion of the light emitting element interposed between the first connection electrode and the second connection electrode.

9. The display device of claim 8, wherein the first pattern and the second pattern are spaced apart from each other with the third side portion of the light emitting element interposed between the first pattern and the second pattern.

10. The display device of claim 1, further comprising a light blocking layer on a side surface of the first pattern and a side surface of the second pattern,
wherein the light blocking layer surrounds at least a part of the light emitting element comprising the first side portion and the second side portion.

11. An electronic device comprising:
a display module comprising a display panel; and
a processor to transmit an image data signal to the display module,
wherein the display panel comprises:
a pixel electrode and a common electrode on a substrate;
an insulating layer on a portion of the pixel electrode and the common electrode;
a light emitting element on the insulating layer, the light emitting element comprising a semiconductor stack, and a first contact electrode and a second contact electrode on a side surface of the semiconductor stack;
a first connection electrode on the insulating layer and on a first side portion of a side surface of the light emitting element, which comprises the first contact electrode, the first connection electrode connecting the first contact electrode and the pixel electrode;
a second connection electrode located on the insulating layer and on a second side portion of the side surface of the light emitting element, which comprises the second contact electrode, the second connection electrode connecting the second contact electrode and the common electrode;
a first pattern on the first connection electrode and surrounding the first side portion of the light emitting element; and
a second pattern on the second connection electrode, surrounding the second side portion of the light emitting element, and spaced apart from the first pattern.

12. The electronic device of claim 11, wherein the first pattern and the second pattern comprise a negative type photoresist material and comprise a side surface having a reverse tapered shape.

13. The electronic device of claim 12, wherein the display panel further comprises:
a first reflective film on a side surface of the first pattern and surrounding the first side portion of the light emitting element; and
a second reflective film on a side surface of the second pattern and surrounding the second side portion of the light emitting element.

14. The electronic device of claim 13, wherein an angle formed by at least a part of the first reflective film and the pixel electrode is 100° to 120°, and
an angle formed by at least a part of the second reflective film and the common electrode is 100° to 120°.

15. The electronic device of claim 11, wherein the first pattern, when viewed in plan view, has a shape and size corresponding to the first connection electrode, and
the second pattern, when viewed in plan view, has a shape and size corresponding to the second connection electrode.

16. The electronic device of claim 11, wherein the display panel further comprises a light blocking layer on a side surface of the first pattern and a side surface of the second pattern, and
the light blocking layer surrounds at least a part of the light emitting element comprising the first side portion and the second side portion.

17. A method for manufacturing a display device, the method comprising:
forming a pixel electrode and a common electrode on a substrate;
forming an insulating layer covering a portion of the pixel electrode and the common electrode;
arranging, on the insulating layer, a light emitting element comprising a semiconductor stack, and a first contact electrode and a second contact electrode on a side surface of the semiconductor stack;
forming a conductive film on the pixel electrode, the common electrode, the insulating layer and the light emitting element;
forming, on the conductive film, a first pattern surrounding a first side portion of a side surface of the light emitting element, which comprises the first contact electrode, and a second pattern surrounding a second side portion of the side surface of the light emitting element, which comprises the second contact electrode; and
forming a first connection electrode surrounding the first side portion of the light emitting element and connecting the first contact electrode and the pixel electrode, and a second connection electrode surrounding the second side portion of the light emitting element and connecting the second contact electrode and the common electrode by etching the conductive film utilizing the first pattern and the second pattern as a mask.

18. The method of claim 17, wherein in the forming of the first pattern and the second pattern, the first pattern and the second pattern are formed in a shape comprising a side surface having a reverse tapered shape, utilizing a negative type photoresist material.

19. The method of claim 18, further comprising forming a first reflective film and a second reflective film on the side surface of the first pattern and the side surface of the second pattern, respectively.

20. The method of claim 18, further comprising forming a light blocking layer on the side surfaces of the first pattern and the second pattern and around at least a part of the light emitting element comprising the first side portion and the second side portion.
